(19) United States
(12) Patent Application Publication
(10) Pub. No.: US 2009/0194233 A1
(43) Pub. Date: Aug. 6, 2009

(54) Component for semicondutor processing apparatus and manufacturing method thereof

(75) Inventors: Akitake Tamura, Nirasaki-shi (JP); Kazuya Dobashi, Nirasaki-shi (JP); Teruyuki Hayashi, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Tokyo Electron Limited, Minato-ku, Tokyo (JP)

(21) Appl. No.: 11/663,182

(22) PCT Filed: Jun. 23, 2006
(86) PCT No.: PCT/JP06/12653

§ 371 Date: Mar. 19, 2007

(30) Foreign Application Priority Data
Jun. 23, 2005 (JP) 2005-183486
Jun. 23, 2005 (JP) 2005-183500
Feb. 22, 2006 (JP) 2006-045490

(51) Int. Cl. C23C 16/455; B32B 15/04; C23C 16/40; C23C 16/44; B05D 1/36; H01L 21/205; H01L 21/306

(52) U.S. Cl. 156/345.1; 428/336; 427/255.31; 427/255.34; 427/255.36; 427/454; 118/715

(57) ABSTRACT

A component (10) for a semiconductor processing apparatus includes a matrix (10a) defining a shape of the component, and a protection film (10c) covering a predetermined surface of the matrix. The protection film (10c) consists essentially of an amorphous oxide of a first element selected from the group consisting of aluminum, silicon, hafnium, zirconium, and yttrium. The protection film (10c) has a porosity of less than 1% and a thickness of 1 nm to 10 μm.

### TECHNICAL FIELD

The present invention relates to a component for a semiconductor processing apparatus, a manufacturing method thereof, and a semiconductor processing apparatus using the component. The term “semiconductor process” used herein includes various kinds of processes which are performed to manufacture a semiconductor device or a structure having wiring layers, electrodes, and the like to be connected to a semiconductor device, on a target object, such as a semiconductor wafer or a glass substrate used for an LCD (Liquid Crystal Display) or FPD (Flat Panel Display), by forming semiconductor layers, insulating layers, and conductive layers in predetermined patterns on the target object.

### BACKGROUND ART

A semiconductor manufacturing apparatus (semiconductor processing apparatus), such as a film formation apparatus, oxidation apparatus, or etching apparatus, includes a process container for performing a predetermined process using a process gas, such as a film formation process, on a semiconductor wafer W (which will be referred to as “wafer W”) to manufacture semiconductor devices. The process container is connected to a process gas supply source for supplying the process gas through a process gas supply line, and is also connected to exhaust means for exhausting the gas from the process container through an exhaust line.

In general, these components, such as the process container, process gas supply line, and exhaust line, are made of a metal, such as electro-polished stainless steel or aluminum. Further, other metal components are included inside the process container. These metal components that constitute a semiconductor manufacturing apparatus are preferably improved in corrosion resistance for use with, e.g., a corrosive gas. For this purpose, a predetermined surface preparation may be applied to the surface of an area that comes in contact with a corrosive gas, such as the internal surface of a process gas supply line or exhaust line, the inner wall of a process container, or the surface of a component located inside a process container.

Surface preparations of this kind are performed by various techniques, such as a fluoride coating film formation process, an ozone passivation process (coating film formation process), an SiO₂ coating process, a ceramic film formation process by thermal spray, an anodic oxidation process, and a CVD (Chemical Vapor Deposition) process. Conventionally, users purchase respective components processed by surface preparations of this kind and assemble them to form a semiconductor manufacturing apparatus. In this case, the components are costly, so the total manufacturing cost of the semiconductor manufacturing apparatus becomes higher. Further, as described later, the present inventors have found that conventional components of this kind entail problems not only in the cost but also in the durability.

### DISCLOSURE OF INVENTION

An object of the present invention is to provide a component with high durability for a semiconductor processing apparatus, a manufacturing method thereof, and a semiconductor processing apparatus using the component.

According to a first aspect of the present invention, there is provided a component for a semiconductor processing apparatus, the component comprising:

a matrix defining a shape of the component; and

a protection film covering a predetermined surface of the matrix,

wherein the protection film consists essentially of an amorphous oxide of a first element selected from the group consisting of aluminum, silicon, hafnium, zirconium, and yttrium, and has a porosity of less than 1% and a thickness of 1 nm to 10 μm.

According to a second aspect of the present invention, there is provided a method for manufacturing a component used for a semiconductor processing apparatus, the method comprising:

preparing a matrix defining a shape of the component; and

forming a protection film covering a predetermined surface of the matrix,

wherein the forming a protection film comprises alternately supplying a first source gas containing a first element and a second source gas containing an oxidation gas, thereby laminating layers formed by CVD (Chemical Vapor Deposition) and having a thickness of an atomic or molecular level, and wherein the first element is selected from the group consisting of aluminum, silicon, hafnium, zirconium, and yttrium.

According to a third aspect of the present invention, there is provided a semiconductor processing apparatus comprising:

a process container having a process field configured to accommodate a target substrate;

a support member configured to support the target substrate within the process field;

an exhaust system configured to exhaust the process field; and

a gas supply system configured to supply a process gas into the process field,

wherein a component forming a part of one of the process field, the exhaust system, and the gas supply system comprises

a matrix defining a shape of the component, and

a protection film covering a predetermined surface of the matrix, and

wherein the protection film consists essentially of an amorphous oxide of an element selected from the group consisting of aluminum, silicon, hafnium, zirconium, and yttrium, and has a porosity of less than 1% and a thickness of 1 nm to 10 μm.

### BRIEF DESCRIPTION OF DRAWINGS

FIG. 1 is a sectional view showing a semiconductor manufacturing apparatus (semiconductor processing apparatus) according to a first embodiment of the present invention;

FIG. 2 is a structural view showing a surface preparation apparatus according to the first embodiment of the present invention, arranged to perform a surface preparation for forming an ALD (Atomic Layer Deposition) film on a component of a semiconductor manufacturing apparatus;

FIG. 3 is a structural view showing an arrangement for forming an ALD film on a metal pipe, by the surface preparation apparatus shown in FIG. 2;

FIG. 4 is a structural view showing an arrangement for forming an ALD film on a component used inside a process container, by the surface preparation apparatus shown in FIG. 2;

FIG. 5 is a flowchart showing a process for forming an ALD film on a metal pipe, by the surface preparation apparatus shown in FIG. 2;

FIG. 6 is a timing chart showing supply of source gases for forming an ALD film on a metal pipe;

FIG. 7 is a flowchart showing a process for forming an ALD film on a component used inside a process container, by the surface preparation apparatus shown in FIG. 2;

FIG. 8 is a structural view showing a surface preparation apparatus according to a modification of the first embodiment of the present invention, arranged to perform a surface preparation for forming an ALD film on a process container, which is a component of a semiconductor manufacturing apparatus;

FIG. 9 is a view schematically showing steps of a process for manufacturing an environment-proof member (component) according to a second embodiment of the present invention;

FIG. 10 is a structural view showing a film formation apparatus according to the second embodiment of the present invention;

FIG. 11A is a view for explaining the open/closed state of valves in the film formation apparatus and the routes of source gases flowing through the apparatus, in a step of a process for forming an intermediate layer (ALD film);

FIG. 11B is a view for explaining the open/closed state of valves in the film formation apparatus and the routes of source gases flowing through the apparatus, in a step of the process for forming an intermediate layer;

FIG. 11C is a view for explaining the open/closed state of valves in the film formation apparatus and the routes of source gases flowing through the apparatus, in a step of the process for forming an intermediate layer;

FIG. 12 is a flowchart showing a film formation process of an intermediate layer;

FIG. 13 is a timing chart showing supply of source gases relative to a film formation apparatus;

FIG. 14 is a side view showing a manner of performing thermal spraying on the surface of a matrix;

FIG. 15 is a sectional view showing a semiconductor processing apparatus according to the second embodiment of the present invention, in which an environment-proof member according to the present invention is used as a component;

FIG. 16 is a structural view showing a film formation apparatus according to a modification of the second embodiment of the present invention;

FIG. 17 is a view schematically showing steps of a process for manufacturing a member according to a conventional process for forming a ceramic thermal spray film;

FIG. 18 is a sectional view showing a semiconductor processing apparatus according to a third embodiment of the present invention;

FIG. 19 is a structural view showing an example of a surface preparation apparatus according to the third embodiment of the present invention, arranged to perform a surface preparation for forming an ALD film on a component of a semiconductor processing apparatus;

FIG. 20 is a structural view showing an arrangement for performing a surface preparation of a process container and a pipe for supplying a process gas into the process container, by the surface preparation apparatus shown in FIG. 19;

FIG. 21 is a flowchart showing the process for performing the surface preparation of the process container and pipe, by the surface preparation apparatus shown in FIG. 19;

FIG. 22 is a timing chart showing supply of source gases for forming an ALD film on a process container and a pipe;

FIG. 23 is a structural view showing an arrangement for performing a surface preparation only of a pipe for supplying a process gas into a process container, by the surface preparation apparatus shown in FIG. 19;

FIG. 24 is a structural view showing an arrangement for performing a surface preparation only of a process container, by the surface preparation apparatus shown in FIG. 19;

FIG. 25 is a structural view showing an arrangement for performing a surface preparation only of a gas pipe for supplying a process gas into a process container, by the surface preparation apparatus shown in FIG. 19;

FIG. 26 is a structural view showing an arrangement for performing a surface preparation only of a gas supply unit disposed on a process gas supply line, by the surface preparation apparatus shown in FIG. 19; and

FIG. 27 is a structural view showing an arrangement for performing a surface preparation only of a process gas supply line for supplying a process gas into a process container, by the surface preparation apparatus shown in FIG. 19.

### BEST MODE FOR CARRYING OUT THE INVENTION

In the process of developing the present invention, the inventors studied problems to arise where each of conventional surface preparation methods is applied to a component for a semiconductor processing apparatus. As a result, the inventors have arrived at the findings given below.

In the case of a fluoride coating film formation process, when a pipe processed by a surface preparation is bent in assembling an apparatus, part of a passivation film (surface preparation film) is broken away at the bent area. Consequently, metal contamination and/or particle generation may be caused. In the case of an oxidation coating film formation process and anodic oxidation process, an oxidation film thereby formed entails difficulty in having a sufficient thickness and thus becomes poor in corrosion resistance. In the case of an SiO₂ coating process, if a pipe to be processed has a small inner diameter, a process cannot be performed thereon. In addition, this process is not suitable for a fluorine atmosphere. In the case of a ceramic thermal spray film formation process, a coating film thereby formed has a porous structure with a rough surface. Consequently, film peeling may occur during a process and cause particle generation. In the case of a CVD process, a compact and good film can be formed, but this process uses a high process temperature and thus is limited in scope of film formation target objects. For example, this process is not suitable for aluminum components.

There is a case where an aluminum process container (film formation chamber) is subjected to a surface preparation for forming thereon a thermal spray film with high corrosion resistance, such as thermal spray of yttria (Y₂O₃) or alumina (Al₂O₃). However, where the container is used for a strongly corrosive process gas or it is exposed to plasma for a long time during a plasma process, film peeling may locally occur in a short time, depending on the process, because the thermal spray film has a porous structure. In this case, it may be necessary to re-perform thermal spraying.

Jpn. Pat. Appln. KOKAI Publication No. 2002-222807 (Patent Document 1) discloses a technique as a countermeasure to a problem of this kind in a heat processing apparatus that includes a process gas supply portion for supplying a process gas, and an exhaust line portion connected to an exhaust system. According to this technique, the gas-contacting surface of a metal member to be exposed to the environment in a process furnace is coated with a chromium oxide coating film, or the gas-contacting surface of a pipe is coated with a fluorine resin coating film. However, as described above, the chromium oxide coating film entails difficulty in having a thickness for sufficient corrosion resistance. Further, the fluorine resin coating film can easily peel off when the pipe having this coating is bent, so metal contamination and/or particle generation may be caused.

Jpn. Pat. Appln. KOKAI Publication No. 2000-290785 (Patent Document 2) discloses a technique for performing a surface preparation by a CVD method. However, the CVD method requires heating at a high temperature of 400 to 500° C. or more, which melts the aluminum of aluminum components. Further, as regards stainless steel pipes, in general, the external surface of a pipe is wrapped with a tape heater to heat it. However, this structure is unusable for realizing a surface preparation by a CVD method, because this structure has trouble in attaining a high temperature of 400 to 500° C. or more.

Embodiments of the present invention achieved on the basis of the findings given above will now be described with reference to the accompanying drawings. In the following description, the constituent elements having substantially the same function and arrangement are denoted by the same reference numerals, and a repetitive description will be made only when necessary.

In the following embodiments, a protection film (deposition film) is formed on the surface of a component used in a semiconductor manufacturing apparatus (semiconductor processing apparatus) to improve the durability of the component and the corrosion resistance thereof relative to a corrosive gas. Examples of the semiconductor manufacturing apparatus encompass those for manufacturing flat panel displays as well as semiconductor devices. Further, examples of the semiconductor manufacturing apparatus encompass an apparatus arranged to use a corrosive gas as a process gas, and an apparatus arranged to supply a corrosive gas as a cleaning gas into a process container, after a substrate process, to process the interior of the process container by use of plasma. Specifically, the apparatuses of these types correspond to etching apparatuses, film formation apparatuses, and ashing apparatuses.

### First Embodiment

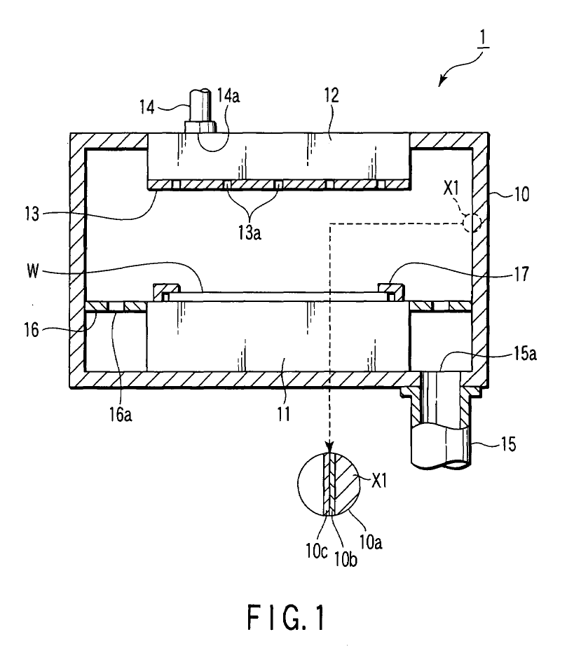

FIG. 1 is a sectional view showing a semiconductor manufacturing apparatus (semiconductor processing apparatus) according to a first embodiment of the present invention. At first, a brief explanation will be given of components used in the semiconductor manufacturing apparatus, which can be set as surface preparation target objects, with reference to the apparatus shown in FIG. 1. In this apparatus, a wafer W is placed on a worktable 11 located inside a process container 10. A gas supply portion (gas showerhead) 12 is disposed to face the worktable 11 inside the process container 10. The showerhead 12 includes a bottom member 13 with a number of gas holes 13a formed therein, through which a process gas of, e.g., a corrosive gas, is supplied onto the wafer W on the worktable 11. The process gas is supplied from a process gas supply line 14 through the gas supply portion 12 into the process container 10. Gas inside the process container 10 is exhausted by exhaust means (not shown) through an exhaust line 15.

The worktable 11 is surrounded by a baffle plate 16 having, e.g., a plurality of gas exhaust ports 16a. The baffle plate 16 allows gas inside the process container 10 to be exhausted from around worktable 11 essentially uniformly in an annular direction. In FIG. 1, there is a mechanical chuck 17 configured to mechanically press the periphery of the wafer W to hold this wafer W on the worktable 11. Of the components of the apparatus shown in FIG. 1, surface preparation target objects are roughly categorized into first components 21 and second components 22. The first components 21 are components each having an internal surface that comes in contact with the process gas, and thus the internal surface is set as a surface preparation target object. The second components 22 are components each having an internal surface and an external surface that come in contact with the process gas, and thus the internal surface and external surface are set as a surface preparation target object.

Specifically, examples of the first components 21 are the process container 10 made of metal, the process gas supply line or pipe 14 for supplying process gas into this process container 10, and the exhaust line or pipe 15 for exhausting gas from inside the process container 10. Other examples of the first components 21 are valves and measuring units, such as flow rate adjusting portions and pressure gauges, disposed on these metal lines or pipes, and gas supply instruments connected to these metal lines or pipes and each having an internal surface that comes in contact with the process gas, such as a gas supply unit combining valves, flow rate adjusting portions, and filters. A surface preparation is performed on surfaces of these components that come in contact with the process gas.

On the other hand, examples of the second component 22 are components located inside the process container 10, as shown in FIG. 1, such as the bottom member 13 of the gas supply portion (gas showerhead) 12, the baffle plate 16, and the mechanical chuck 17. A surface preparation is performed on surfaces of these components that come in contact with the process gas.

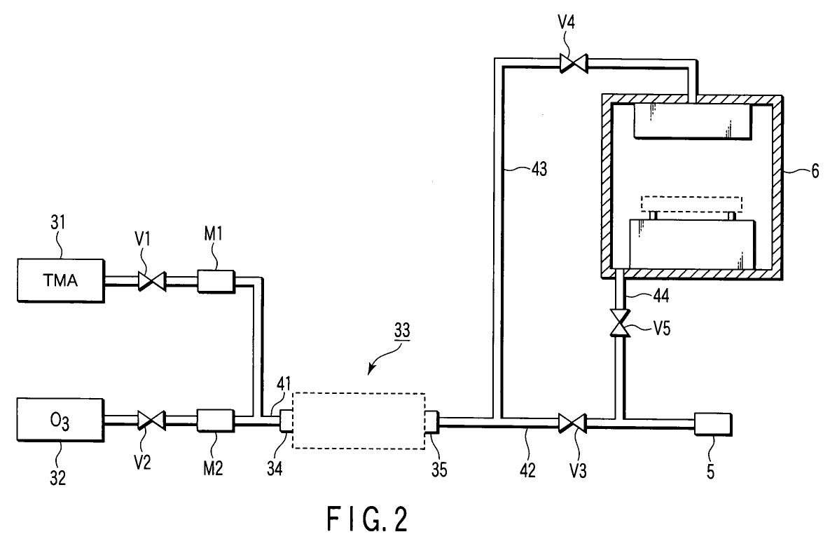

FIG. 2 is a structural view showing a surface preparation apparatus according to the first embodiment of the present invention, arranged to perform a surface preparation for forming an ALD (Atomic Layer Deposition) film on a component of a semiconductor manufacturing apparatus. As an example used in the following explanation, a surface preparation is arranged to form an Al₂O₃ film, which is a compound containing aluminum (Al), as a deposition film (protection film) on a surface of a component.

As shown in FIG. 2, a supply source (first source gas supply source) 31 is disposed to supply trimethyl aluminum (TMA: Al(CH₃)₃) as a first source gas. The first source gas supply source 31 includes a gasification mechanism for TMA. A supply source (second source gas supply source) 32 is disposed to supply ozone (O₃) gas as a second source gas. A connecting portion 33 is located downstream from these first and second source gas supply sources 31 and 32. The first and second source gas supply sources 31 and 32 are connected to the connecting portion 33 through a first source material flow passage 41 provided with, e.g., first and second switching valves V1 and V2 and first and second mass-flow controllers M1 and M2.

The downstream side of this connecting portion 33 is connected to vacuum exhaust means, such as a vacuum pump 5, through a second source material flow passage 42 provided with a switching valve V3. The downstream side of this connecting portion 33 is also connected to a film formation container 6, which is used for performing a surface preparation of a second component 22, through a third source material flow passage 43 provided with a switching valve V4. This film formation container 6 is connected to a portion of the second source material flow passage 42 between the switching valve V3 and vacuum pump 5 through a fourth source material flow passage 44 provided with a switching valve V5.

The connecting portion 33 is configured to connect a first component 21 to the first and second source material flow passages 41 and 42, when the first component 21 is a surface preparation target object. For example, at this connecting portion 33, the ends of the first and second source material flow passages 41 and 42 to be connected to the first component 21 are respectively provided with connector members 34 and 35. The connector members 34 and 35 are used to connect the pipes of the source material flow passages 41 and 42 to the opposite connection ends of the first component 21.

The connector members 34 and 35 are used when the connection ends of the first component 21 have opening sizes different from those of the source material flow passages 41 and 42. Each of the connector members 34 and 35 is connected to the source material flow passage 41 (or 42) on one side, and is connected to the first component 21 on the other side. Consequently, a flow passage for the source gases is formed inside this connector member.

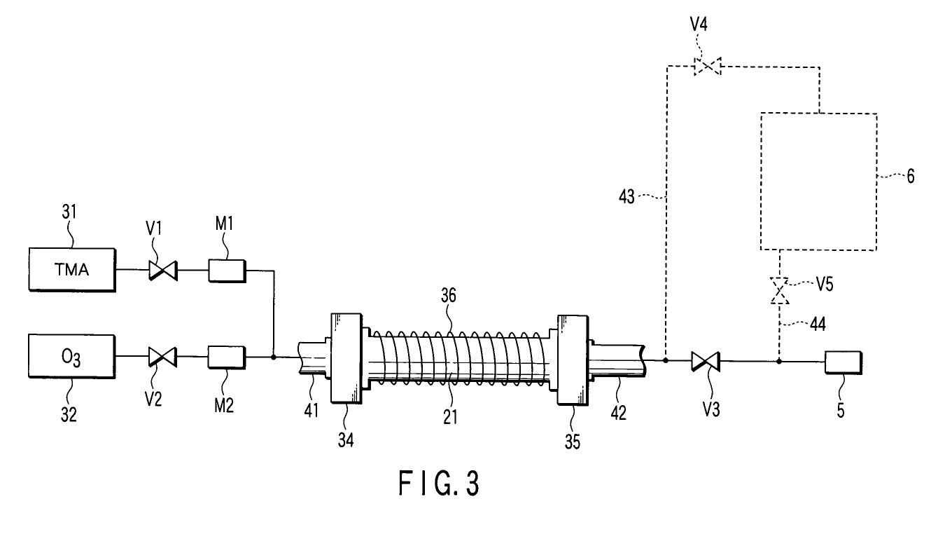

FIG. 3 is a structural view showing an arrangement for forming an ALD film on a metal pipe (first component 21), by the surface preparation apparatus shown in FIG. 2. For example, where the first component 21 is a metal pipe, such as the process gas supply line 14 or exhaust line 15, the opposite ends of the metal pipe are connected to the first and second source material flow passages 41 and 42 through the connector members 34 and 35, as shown in FIG. 3. After the metal pipe is connected at the connecting portion 33, for example, the external surface of this pipe is wrapped with a tape heater 36 to heat the pipe.

A plurality of sets of connector members 34 and 35 are prepared in accordance with, e.g., the connection end openings of first components 21. However, where the opening sizes of a first component 21 at the connection portions are the same as those of the pipes of the source material flow passages 41 and 42, there is no need to use any connector members 34 and 35. Alternatively, for example, pipes may be respectively provided with flange portions at the connection ends to directly connect them by the flange portions.

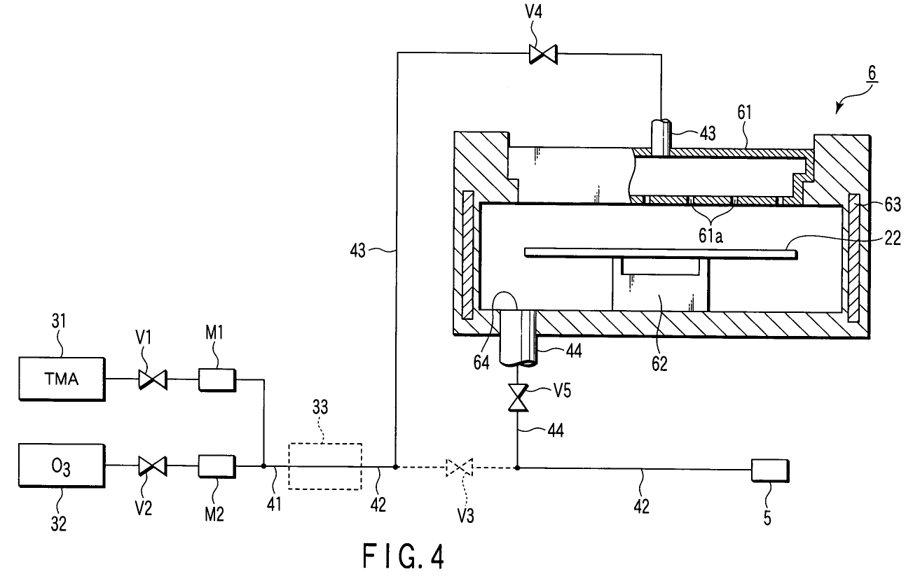

FIG. 4 is a structural view showing an arrangement for forming an ALD film on a component (second component 22) used inside a process container, by the surface preparation apparatus shown in FIG. 2. For example, the film formation container 6 for performing a surface preparation of a second component 22 has an internal surface formed of an alumina thermal spray film. The film formation container 6 is provided with a gas supply portion 61 located inside on the top and connected to the other end of the third source material flow passage 43. The gas supply portion 61 has a number of source gas supply holes 61a formed in the bottom. The film formation container 6 is also provided with, e.g., a support table 62 located inside on the bottom and facing the gas supply portion 61. The second component 22 set as a surface preparation target object is placed on this support table 62. The surfaces of the gas supply portion 61 and support table 62 that come in contact with surface preparation source gases are made of, e.g., aluminum. A heater 63, such as a resistive heating body, is embedded in a wall of the film formation container 6. An exhaust port 64 is formed at the bottom of the film formation container 6 and is connected to the vacuum pump 5 through the fourth source material flow passage 44 and second source material flow passage 42.

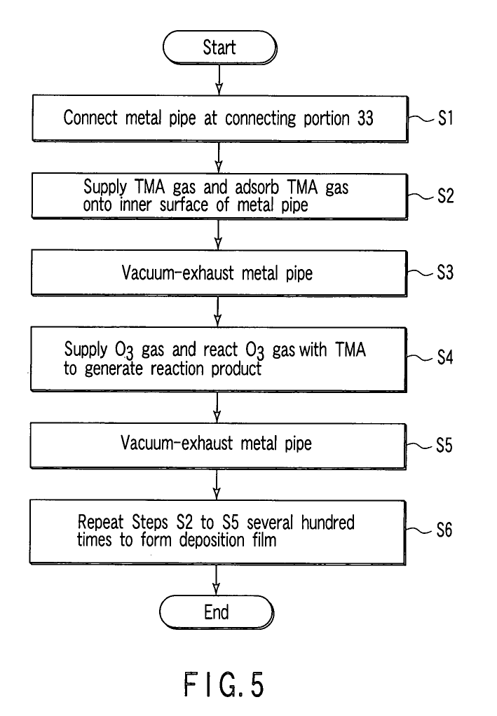

FIG. 5 is a flowchart showing a process for forming an ALD film on a metal pipe (first component 21), by the surface preparation apparatus shown in FIG. 2. For example, this process is performed before an apparatus is assembled or when an apparatus is subjected to a maintenance operation. An explanation will first be given of a case where a surface preparation is arranged to form a deposition film for the process gas supply line 14 or exhaust line 15 set as a first component 21. For example, where the process gas supply line 14 and exhaust line 15 are formed of a metal matrix, such as stainless steel or aluminum, a deposition film is formed on the surface of this metal matrix.

At first, as shown in FIG. 3, a metal pipe of, e.g., the process gas supply line 14 or exhaust line 15 is connected at the connecting portion 33, as described above (Step S1). Then, the internal surface of the metal pipe is heated by, e.g., a tape heater 36 to e.g., about 150° C. Further, the valves V1, V2, V4, and V5 are closed, the valve V3 is opened, and the interior of the metal pipe is vacuum-exhausted by the vacuum pump 5 to, e.g., about 133 Pa (1 Torr).

Then, the valve V3 is closed, the valve V1 is opened, and the first source gas or TMA gas is supplied into the metal pipe at a flow rate of, e.g., about 100 ml/min for about 1 second. Consequently, TMA gas is adsorbed on the internal surface of the surface preparation target object or metal pipe (Step S2).

Then, the valve V1 is closed, the valve V3 is opened, and the interior of the metal pipe is vacuum-exhausted for about 2 seconds (Step S3). Consequently, the residual part of the first source gas, which is not adsorbed on the internal surface of the metal pipe and thus is suspended inside the metal pipe, is exhausted. Then, the valve V3 is closed, the valve V2 is opened, and the second source gas or O₃ gas is supplied into the metal pipe at a flow rate of, e.g., about 1,000 ml/min for about 1 second. The O₃ gas reacts with liquid TMA adsorbed on the metal pipe, and thereby generates a reaction product (in a solid phase) that is expressed by a chemical formula of Al₂O₃. Consequently, a very thin compound layer (oxide layer) made of Al₂O₃ is formed to have a film thickness of, e.g., about 0.1 nm (Step S4).

Then, the valve V2 is closed, the valve V3 is opened, and the interior of the metal pipe is vacuum-exhausted for about 2 seconds (Step S5). Consequently, the residual part of O₃ gas inside the metal pipe is exhausted. The Steps S2 to S5 are repeated, e.g., several hundred times, so that a deposition film is formed to have a film thickness of, e.g., 30 nm (Step S6).

As described above, according to this embodiment, a metal matrix set as a process target object is first exposed to a first source gas atmosphere, so the first source gas is adsorbed on the matrix surface. Then, this atmosphere is switched to a second source gas atmosphere that reacts with the first source gas. Consequently, a compound layer is formed to have a film thickness of, e.g., about 0.1 nm. The atmospheres to which the matrix is exposed are alternately switched a number of times between the first source gas atmosphere and second source gas atmosphere. The compound layers thus formed are laminated on the matrix surface, so a deposition film is formed from the compound layers.

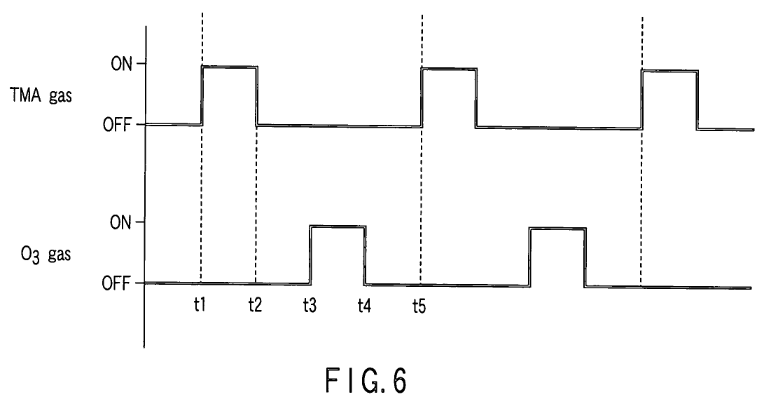

FIG. 6 is a timing chart showing supply of source gases for forming an ALD film on a metal pipe. As shown in FIG. 6, TMA gas and O₃ gas are alternately supplied into the first component 21. Further, during each of the periods (period of t2 to t3 and period of t4 to t5) between the gas supply periods, the interior of the metal pipe is exhausted at full load for, e.g., 2 seconds. Consequently, a very thin Al₂O₃ film is formed on the internal surface of the metal pipe. One cycle formed of the steps between times t1 to t5 is repeated, e.g., several hundred times, so that a deposition film consisting of Al₂O₃ films is formed to have a film thickness of, e.g., 30 nm on the internal surface of the metal pipe.

Where the first component 21 is a metal process container, such as the process container 10, the matrix thereof is made of aluminum or a substrate having a surface with a thermal spray film (consisting of poly-crystal) formed thereon, such as an aluminum or yttria thermal spray film. Accordingly, a deposition film is formed on the surface of the matrix or thermal spray film. For example, the thermal spray film is made of a material containing boron (B), magnesium (Mg), aluminum (Al), silicon (Si), gallium (Ga), chromium (Cr), yttrium (Y), zirconium (Zr), tantalum (Ta), germanium (Ge), or neodymium (Nd).

Also in this case, at the connecting portion 33 as in a case for a metal pipe, the process gas supply port 14a (see FIG. 1) of the process container 10, which serves as a connecting portion to the process gas supply line 14, is connected to the first source material flow passage 41 through the connector member 34. Further, the exhaust port 15a (see FIG. 1) of the process container 10, which serves as a connecting portion to the exhaust line 15, is connected to the second source material flow passage 42 through the connector member 35. Then, in accordance with the steps shown in FIG. 5, a surface preparation is performed to form a deposition film on the internal surface of the process container 10. FIG. 1 includes an auxiliary portion X1, shown as enlarged, which shows the relationship between the matrix 10a, thermal spray film 10b, and ALD film 10c around the internal surface of the process container 10 thus prepared.

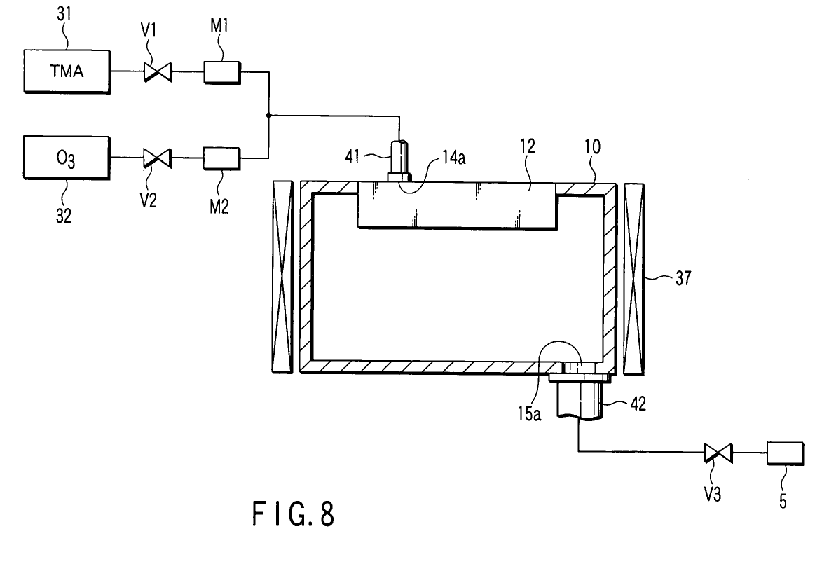

FIG. 8 is a structural view showing a surface preparation apparatus according to a modification of the first embodiment of the present invention, arranged to perform a surface preparation for forming an ALD film on a process container, which is a component of a semiconductor manufacturing apparatus. As shown in FIG. 8, a surface preparation may be performed on the internal surface of the process container 10 by use of an apparatus exclusively used for the same. This apparatus is a modification of the surface preparation apparatus shown in FIG. 2, wherein the process container 10 is connected between the first and second source material flow passages 41 and 42. The downstream end of the first source material flow passage 41 and the upstream end of the second source material flow passage 42 serve as connection ends exclusively used for connection to the process gas supply port 14a and exhaust port 15a, respectively. In other words, this apparatus has the same arrangement as the apparatus shown in FIG. 2 except that the film formation container 6 and the third and fourth source material flow passages 43 and 44 are omitted.

When in use, at first, the process container 10 set as a surface preparation target object is connected between the first and second source material flow passages 41 and 42. Then, heating means, such as a resistive heating body 37, is disposed around, e.g., the sidewall of the process container 10, and the process container 10 is thereby heated. In the case of a surface preparation performed on the internal surface of the process container 10, the process can be performed in a state where the gas supply portion 12 is attached to the process container 10. Alternatively, the process may be performed in a state where the gas supply portion 12 is detached. In this case, another surface preparation is independently performed on the gas supply portion 12, which is attached to the process container 10 thereafter.

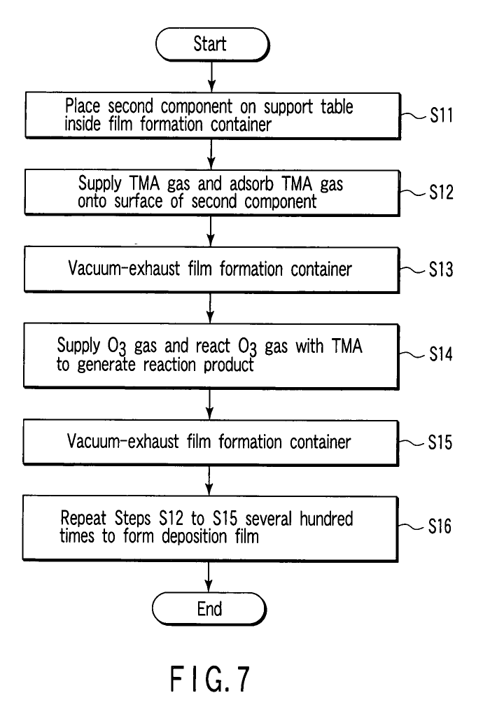

FIG. 7 is a flowchart showing a process for forming an ALD film on a component (second component 22) used inside a process container, by the surface preparation apparatus shown in FIG. 2. The matrix of a second component 21, such as the bottom member 13 of the gas supply portion 12, the baffle plate 16, or the mechanical chuck 17, is made of a metal, such as stainless steel or aluminum, and thus a deposition film is formed on the surface of this matrix.

In this case, as shown in FIGS. 2 and 4, the first and second source material flow passages 41 and 42 are directly connected to each other at the connecting portion 33, and the second component 22 is placed on the support table 62 inside the film formation container 6 (Step S11). Then, the internal surface of the film formation container 6 is heated by, e.g., the heater 63 to, e.g., about 150° C. Further, the valves V1, V2, V3, and V4 are closed, the valve V5 is opened, and the interior of the film formation container 6 is vacuum-exhausted by the vacuum pump 5 to, e.g., about 133 Pa (1 Torr).

Then, the valve V5 is closed, the valves V1 and V4 are opened, and the first source gas or TMA gas is supplied into the film formation container 6 at a flow rate of, e.g., about 100 ml/min for about 1 second. Consequently, TMA gas is adsorbed on the surface of the second component 22 in contact with the first source gas (Step S12). Then, the valves V1 and V4 are closed, the valve V5 is opened, and the interior of the film formation container 6 is vacuum-exhausted for about 2 seconds to exhaust the residual part of TMA gas (Step S13).

Then, the valve V5 is closed, the valves V2 and V4 are opened, and the second source gas or O₃ gas is supplied into the film formation container 6 at a flow rate of, e.g., about 1,000 ml/min for about 1 second. Consequently, a very thin compound layer (oxide layer) made of Al₂O₃ is formed to have a film thickness of, e.g., about 0.1 nm (Step S14). Then, the valves V2 and V4 are closed, the valve V5 is opened, and the interior of the film formation container 6 is vacuum-exhausted for about 2 seconds to exhaust the residual part of O₃ gas (Step S15). The Steps S12 to S15 are repeated, e.g., several hundred times, so that a deposition film consisting of Al₂O₃ films is formed to have a film thickness of, e.g., 30 nm on the surface of the second component 22 (Step S16). It should be noted that, since the deposition film can be formed even at a low temperature of, e.g., from about room temperature to 200° C., heating by the tape heater 36, resistive heating body 37, and heater 63 is not necessarily required.

Further, in the surface preparation method described above, when the interior of a process target object (the metal pipe or film formation container 6 in the examples described above) is vacuum-exhausted in Steps 3 and 13, nitrogen (N₂) gas used as a purge gas may be supplied to purge the interior of the process target object. Where nitrogen gas is supplied during vacuum exhaust, the residual part of TMA gas suspended inside the process target object is efficiently exhausted.

Further, when the interior of a process target object is vacuum-exhausted in Steps 3 and 13, the pressure inside the process target object may be set higher than that described above. In this case, the amount of TMA gas adsorbed on the internal surface of the process target object is increased, so a film thickness formed by one reaction becomes larger. Contrary, the pressure inside the process target object may be set lower than that described above, so that a film thickness formed by one reaction becomes smaller.

Where this process is first performed in fabricating a semiconductor manufacturing apparatus, a surface preparation is performed to form a deposition film on the surface of first components 21 and second components 22 that comes in contact with a process gas. Then, these first components 21 and second components 22 are assembled to fabricate the semiconductor manufacturing apparatus. Where this process is performed periodically or as needed for maintenance of a semiconductor manufacturing apparatus, components to be processed by a surface preparation is first detached from the semiconductor manufacturing apparatus. Then, a surface preparation is performed to form a deposition film on the surface of these components that comes in contact with a process gas. Then, these components are attached to the semiconductor manufacturing apparatus.

Other than an Al₂O₃ film formed by the method described above, a deposition film may be formed from an organo-metallic compound containing aluminum (Al), hafnium (Hf), zirconium (Zr), or yttrium (Y). Alternatively, a deposition film may be formed from a compound, such as a chloride, containing aluminum (Al), hafnium (Hf), zirconium (Zr), or yttrium (Y).

In this respect, specific examples are as follows. A first source gas comprising Al(T-OC₄H₉)₃ gas and a second source gas comprising H₂O gas are used to form Al₂O₃. A first source gas comprising HfCl₄ gas and a second source gas comprising O₃ gas are used to form HfO₂. A first source gas comprising Hf(N(CH₃)(C₂H₅))₄ gas and a second source gas comprising O₃ gas are used to form HfO₂. A first source gas comprising Hf(N(C₂H₅)₂)₄ gas and a second source gas comprising O₃ gas are used to form HfO₂. A first source gas comprising ZrCl₄ gas and a second source gas comprising O₃ gas are used to form ZrO₂. A first source gas comprising Zr(T-OC₄H₉)₄ gas and a second source gas comprising O₃ gas are used to form ZrO₂. A first source gas comprising YCl₃ gas and a second source gas comprising O₃ gas are used to form Y₂O₃. A first source gas comprising Y(C₅H₅)₃ gas and a second source gas comprising O₃ gas are used to form Y₂O₃.

According to this embodiment, in the case of a first component 21, the source gases are supplied into the first component 21. In the case of a second component 22, the second component 22 is placed inside the film formation container 6 and the source gases are supplied into the film formation container 6. By doing so, compound layers are laminated to form a thin film, which brings about a deposition film formed all over the internal surface of the first or second component 21 or 22. Consequently, the durability of the components 21 and 22 is improved.

Specifically, according to this deposition method, since a deposition film is formed by laminating very thin compound layers, the film is formed as a dense film having high durability and corrosion resistance against a corrosive process gas. Further, the film thus formed has a high surface flatness, which can prevent film peeling or the like from occurring due to surface roughness.

Further, according to this embodiment, a surface preparation is arranged such that the source gases are supplied onto a component set as a surface preparation target object, in the same way as a process gas, such as a corrosive gas, being supplied. Consequently, the source gases are supplied to the area of this component that comes in contact with the process gas. For example, a surface preparation can be performed to form a deposition film on the internal surface of a component 21 that comes in contact with the process gas.

Since a vacuum process is used to form a deposition film, the source gases are delivered to narrow places to form the deposition film on such places. For example, a deposition film can be formed even on the internal surface, which comes in contact with a process gas, of valves and flow rate adjusting portions disposed on pipes, which are regarded as first components 21, and even on the surface of the complex shapes of second components 22.

The deposition film is formed by laminating very thin layers (having an atomic or molecular level thickness) one by one, as described above. Accordingly, the thickness of the deposition film can be set at a desired value by controlling the number of repetitions of Steps S2 to S5 (or Steps S12 to S15). For example, depending on the surface preparation target object, the thickness of the deposition film can be easily adjusted. Specifically, where the target object has a complex shape, such as a gas supply unit combining a number of pipes, and valves, flow meters, and filters connected thereto, the surface preparation is arranged to form a deposition film having a small film thickness. In this case, it is possible to improve the corrosion resistance of the target object relative to a corrosive gas without impeding the gas flow conductance.

Vacuum exhaust is performed between the supply periods of the first and second source gases, so that the second source gas is supplied in a state where no first source gas remains. In this case, the first and second source gases are prevented from reacting with each other inside a component 21 or inside the film formation container 6, and thus particle generation due to reaction products is suppressed.

As described above, a dense film can be formed all over the surface of a component that comes in contact with a process gas. Consequently, the corrosion resistance of the component relative to a corrosive process gas is improved. Further, particle generation due to corrosion of the component is suppressed.

The deposition film is formed by a process at a temperature of, e.g., from about room temperature to 200° C., which is lower than that used in thermal CVD methods in general. Accordingly, even for a process container made of, e.g., aluminum or aluminum with a thermal spray film formed thereon, a surface preparation can be performed without melting aluminum. Where the deposition film is formed on a thermal spray film, which is porous, the deposition film is formed from compound layers that intrude a number of holes of the thermal spray film, and thus the deposition film becomes stronger. In this case, the corrosion resistance of the thermal spray film, which is originally high, is enhanced by the dense deposition film formed on the thermal spray film. Further, a weak point of the thermal spray film, i.e., the porous structure or surface roughness thereof, can be compensated for by the deposition film. Consequently, even where a corrosive process gas is used, it is possible to prevent film peeling from occurring during the process.

Also in a case where a surface preparation is performed for a metal pipe, the deposition film is formed by a low temperature process, as described above. At this time, the reaction between the first and second source gases can sufficiently proceed even by heating of the tape heater 36. Accordingly, the process can be performed by use of a simple heating method.

As described above, according to this embodiment, a surface preparation is performed to form a deposition film on a component made of aluminum or stainless steel, such as a process container, pipe, or bottom member, in a state where it has not undergone a surface preparation and thus is inexpensive. Consequently, the durability of the component and the corrosion resistance thereof relative to a corrosive gas are improved. In this case, a semiconductor manufacturing apparatus can be assembled from inexpensive components, without purchasing expensive components processed by a surface preparation in advance, so the manufacturing cost of the apparatus can be decreased.

The arrangement shown in FIG. 2 can be used as an apparatus for performing a surface preparation of a component. For example, in the case of a first component 21, such as a metal pipe, a surface preparation is performed while the first component 21 is connected at the connecting portion 33. In the case of a second component 22, a surface preparation is performed while the second component 22 is placed in the film formation container 6. Surface preparations for the first and second components 21 and 22 can be selectively performed while the switching valves on the source material supply passages are switched. Further, surface preparations on the first and second components 21 and 22 can be performed at the same time. In this latter case, the first component 21, such as a metal pipe, is connected at the connecting portion 33, and the second component 22 is placed in the film formation container 6. When the source gases are supplied, it is supplied onto both of the first and second components 21 and 22. When vacuum exhaust is performed, it is performed on both of the first and second components 21 and 22. In other words, a single apparatus can be used to perform a surface preparation for either or both of the first and second components 21 and 22, so the apparatus has high versatility.

However, an apparatus exclusively used for each component may be employed to perform a surface preparation for the component. For example, a surface preparation apparatus including no film formation container 6 and thus exclusively used for metal pipes or a surface preparation apparatus exclusively used for the process container 10 may be employed, as suggested by the process container 10 shown in FIG. 8. Alternatively, a surface preparation apparatus including only the film formation container 6 without the connecting portion 33 and thus exclusively used for a second component 22 may be employed. In this case, surface preparations can be performed in parallel for different components in different processing apparatuses, thereby improving the throughput in surface preparation.

According to this embodiment, a component used in an apparatus for performing steps of a semiconductor manufacture process is set as a surface preparation target object to be processed. Examples of such a component encompass not only a metal component described above, but also components formed of an aluminum matrix with an alumite-processed surface, an electrode plate, a focus ring, and members, such as a deposition shield, made of resin, e.g., PEEK (polyetheretherketone). Where a surface preparation is performed for one of these components to form a deposition film thereon, the durability of this component is improved.

In this embodiment, a surface preparation may be arranged to process the internal surface of the process container 10 and a second component 22 at the same time, in a state where the second component 22 is attached to the process container 10. Further, in this embodiment, where a surface preparation is performed on the internal surface of the process container 10, the process container 10 may be connected in place of the film formation container 6, at the connecting portion for the container 6 shown in FIG. 2.

Examples of a second component 22 are components used in an apparatuses for performing steps of a semiconductor manufacture process, such as the bottom member 13 of the gas supply portion 12, the baffle plate 16, and the mechanical chuck 17, as described above. These components encompass all the components located inside the process container of a semiconductor manufacturing apparatus, in which a process gas is supplied into the process container to process a substrate.

### Experiment in Relation to First Embodiment

In order to confirm effects of this embodiment, the following experiments were carried out.

(Fabrication of Sample)

In the surface preparation apparatus shown in FIG. 4, a deposition film of Al₂O₃ was formed on the surface of a stainless steel matrix. At first, the stainless steel matrix was placed on the support table 62 inside the film formation container 6 shown in FIG. 4, and was heated to 200° C. by the heater 63. Further, the interior of the film formation container 6 was vacuum-exhausted to about 133 Pa. Then, TMA gas was supplied into the film formation container 6 at a flow rate of 100 ml/min for about 1 second. Then, the interior of the film formation container 6 was vacuum-exhausted for about 5 seconds. Then, water vapor was supplied into the film formation container 6 at a flow rate of 100 ml/min for about 1 second. These steps were repeated 100 times to form a deposition film on the stainless steel matrix. This stainless steel matrix was labeled as Sample 1.

The surface of another stainless steel matrix was subjected to a surface roughening process by abrasive blasting. Then, a thermal spray film of Al₂O₃ was formed on the matrix by a plasma thermal spray process. Then, a deposition film was formed on this thermal spray film by the same processing method as in Sample 1. This stainless steel matrix was labeled as Sample 2.

(Adhesion Test)

Sample 1 and Sample 2 were tested in terms of the adhesion degree of the deposition film formed on the surface of the stainless steel matrix. In this test, an adhesive tape was attached to and then detached from the deposition film surface, followed by observation on the condition of part of the deposition film transferred to the adhesive tape. By doing so, the adhesion strength between the deposition film and stainless steel matrix, and the adhesion strength between the deposition film and thermal spray film were respectively evaluated. As a result of this test, in either of Sample 1 and Sample 2, no part of the deposition film was transferred or peeled off onto the adhesive tape when the adhesive tape was detached. Accordingly, it was confirmed that both of the adhesion strength between the deposition film and stainless steel matrix, and the adhesion strength between the deposition film and thermal spray film had no problem.

(Corrosion Resistance Test)

A corrosive test was performed on Sample 1 and a comparative sample formed of a stainless steel matrix not processed by this embodiment. Specifically, at first, the comparative sample and Sample 1 were placed inside the chamber, and fluorine (F₂) gas set at a flow rate of 3 L/min and nitrogen (N₂) gas set at a flow rate of 8 L/min were supplied into the chamber. Further, the pressure inside the chamber was set at 50 kPa, and the comparative sample and Sample 1 were left unattended for 1 hour. The corrosion resistance of the surface of these samples thus processed was evaluated. Thereafter, the comparative sample and Sample 1 were unloaded from the chamber, and the depth profile of the surface of these samples was measured by an X-ray electron spectroscopic analysis (XPS) apparatus. As a result, in the profile of the comparative sample, such a phenomenon was observed that chromium (Cr) was desorbed from the surface of the deposition film and corrosion of the stainless steel matrix proceeded as time proceeded. On the other hand, in the profile of Sample 1, only the uppermost surface portion of the deposition film was slightly changed to aluminum fluoride (AlF₃) without a substantial change in the film thickness. Accordingly, it has been confirmed the deposition film formed on the surface of a stainless steel matrix effectively ensures a large corrosion resistance relative to the corrosive gas.

<Consideration about Thermal Spray Film Formation Process>

According to thermal spray film formation processes, a thermal spray material is melted and sprayed (which will be referred to as thermal spray) onto a matrix surface. The thermal spray material intrudes into recesses present on the matrix surface and coheres with the matrix surface by means of a physical force, such as a contractive stress, whereby a thermal spray film is formed. This process has the following three advantages. (1) This process is applicable to most of the materials as well as metal and most of the members (matrix) having a complex shape. (2) This process can provide a thick coating film in a very short time. (3) Where ceramic is used as a thermal spray material in this process, high corrosion resistance is obtained by the ceramic. However, in return, this process has a disadvantage in that a thermal spray film can easily peel off from a matrix, because a strong bonding force, such as a chemical bonding force or intermolecular force does not act between, e.g., the metal matrix and ceramic thermal spray film.

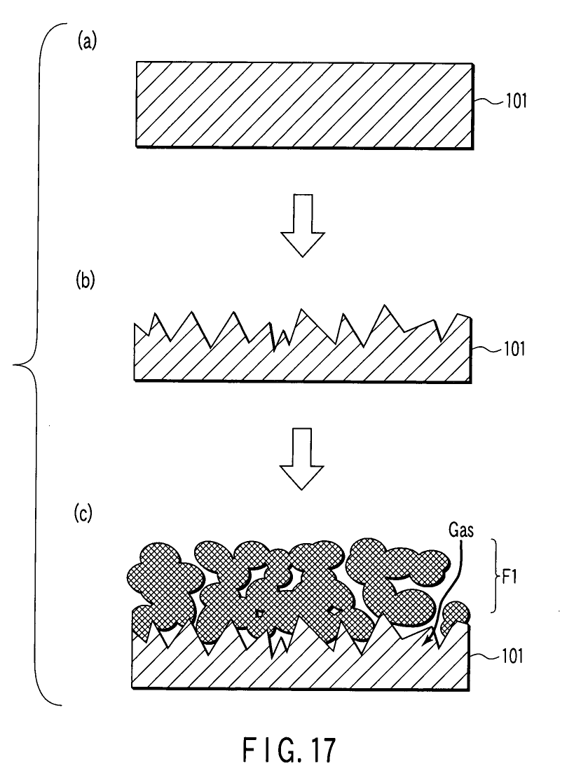

In this respect, there is known a technique in which a surface roughening process is performed on a matrix surface to prevent a thermal spray film from peeling off the matrix surface. FIG. 17 is a view schematically showing steps of a process for manufacturing a member according to a conventional process for forming a ceramic thermal spray film. For example, in a sand abrasive blasting method, sand-like abrasive grains are blown by compressed gas onto a metal matrix surface shown in FIG. 17, (a), and the surface is thereby roughened, as shown in FIG. 17, (b). Then, a ceramic thermal spray film F1 is formed on the matrix surface thus processed, as shown in FIG. 17, (c). A large contacting area thereby obtained between the ceramic thermal spray film F1 and matrix 101 improves the bonding force, so the ceramic thermal spray film F1 is prevented from peeling off. However, even where this process is performed, the force acting between the matrix 101 and ceramic thermal spray film F1 cannot be changed to a stronger bonding force (such as a chemical bonding force or intermolecular force). Consequently, such a problem is still pending that the ceramic thermal spray film F1 may peel off the matrix 101.

Further, since the ceramic thermal spray film F1 is formed from particles of the thermal spray material thus sprayed and stacked, the film has a porous structure including a number of pores. Where a member coated with such a thermal spray film is located in a corrosive gas or plasma environment, the corrosive gas or plasma may flow through pores formed in the thermal spray film, as shown in FIG. 17, (c), and reach the matrix surface. Consequently, the matrix 101 is corroded by the corrosive gas or the matrix 101 is exposed to and damaged by the plasma. In this case, the ceramic thermal spray film F1 peels off, starting from damaged portions, thereby shortening the service life of the member.

Metal materials processed by thermal spray film formation are frequently used for, e.g., process containers in film formation apparatuses arranged to use a corrosive gas as a process gas or cleaning gas, and etching apparatuses and ashing apparatuses arranged to use plasma. In these apparatuses, if a thermal spray film peels off, problems arise not only about a decrease in the service life of a component, but also about a decrease in product yield due to particle generation. Further, where a thermal spray film is formed on the surface of a ceramic matrix, the thermal spray film cannot intrude into minute recesses on the matrix due to poor wettability, depending on the ceramic material. Accordingly, the thermal spray film can peel off ceramic matrixes more easily as compared to metal matrixes.

Jpn. Pat. Appln. KOKAI Publication No. 2000-103690 (Patent Document 3) discloses, in its eighth paragraph to ninth paragraph, discloses a technique as a countermeasure to the problem described above. According to this technique, metal plating having high adhesiveness is applied as an intermediate layer onto the surface of a ceramic matrix, and a metal thermal spray film is formed on this intermediate layer. The intermediate layer having high adhesiveness serves as an anchor to improve the adhesiveness of the thermal spray film. However, this technique is conceived to improve the adhesiveness of a metal thermal spray film, and is not arranged to address other problems.

Further, according to the technique disclosed in Patent Document 3, a liquid is used to form an intermediate layer (metal plating) on a matrix surface. However, the intermediate layer may insufficiently intrude into minute recesses on the matrix surface due to poor wettability of the matrix surface and so forth. In this case, the intermediate layer cannot sufficiently serve as an anchor, and thus the thermal spray film may peel off along with the intermediate layer.

### Second Embodiment

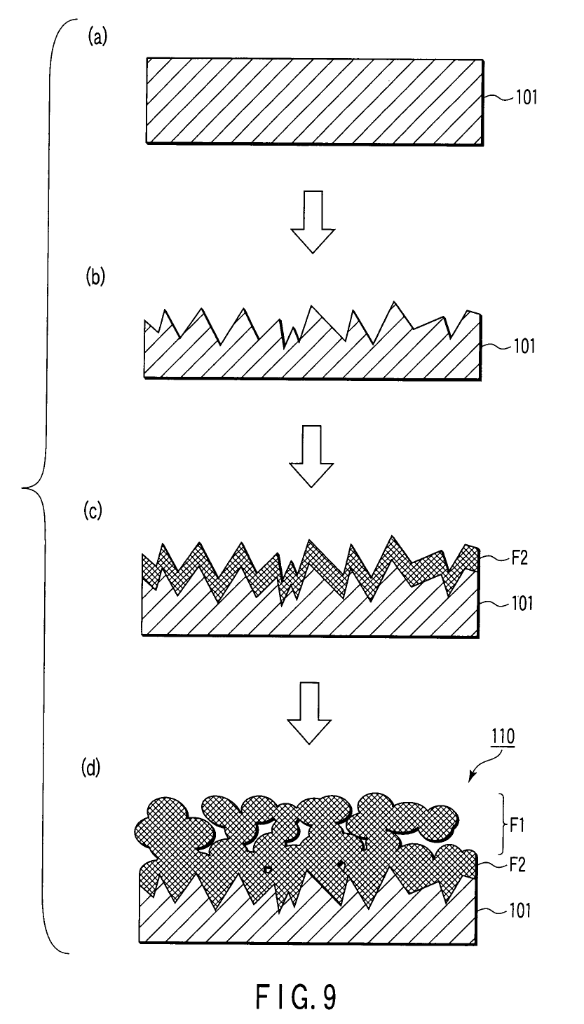

FIG. 9 is a view schematically showing steps of a process for manufacturing an environment-proof member (component) according to a second embodiment of the present invention. In FIG. 9, (a) to (d) are views schematically showing a cross-section of a matrix 101 with a film formed on the surface, in the respective steps. According to this embodiment, a surface roughening process is performed on the matrix 101 (FIG. 9, (a)) to be processed by a surface preparation, so that the specific surface area of the matrix is increased (FIG. 9, (b)). Then, an intermediate layer (protection film) F2 is formed (FIG. 9, (c)), and a thermal spray material is thermally sprayed onto the surface of the intermediate layer F2 to form a ceramic thermal spray film F1 (FIG. 9, (d)).

The material of the matrix 101 is selected from metal materials, such as aluminum and stainless steel, in accordance with the intended use and process recipe of a component. For example, the surface roughening process applied onto the selected matrix 101 is a sand abrasive blasting method. In the sand abrasive blasting method, sand-like abrasive grains are blown by compressed gas to shave a matrix surface, thereby forming minute recesses (roughening). The abrasive grains are selected from sand grains of, e.g., silicon carbide and metal grains, in accordance with the material of the matrix 101. However, this process may be modified such that the intermediate layer F2 and ceramic thermal spray film F1 are formed on the matrix 101 without performing the surface roughening process.

The intermediate layer F2 is formed by the following method on the matrix 101 after the surface roughening process. The intermediate layer F2 is a thin film made of a ceramic material, such as alumina, and formed to intrude into recesses on the roughened matrix surface, as shown in FIG. 9, (c).

Then, a thermal spray material is thermally sprayed onto the surface of the intermediate layer F2 to form the ceramic thermal spray film F1, thereby manufacturing an environment-proof member 110. The ceramic thermal spray film F1 is a thin film formed on the surface of the intermediate layer F2 by thermal spray (melting and spraying) of a ceramic, such alumina. The ceramic thermal spray film F1 is formed such that a thermal spray material applied by thermal spray solidifies on the intermediate layer F2. Consequently, as shown in FIG. 9, (d), the film F1 has a porous structure comprising a number of deposited particles (made of poly-crystal). In principle, the ceramic thermal spray film F1 and intermediate layer F2 are bonded to each other while the thermal spray material intrudes into recesses on the surface of the intermediate layer F2 and coheres therewith by a physical force, such as a contractive stress. The materials of the ceramic thermal spray film F1 and intermediate layer F2 are selected from ceramics having the same or close melting points. In this case, for example, where a thermal spray material is thermally sprayed at a temperature higher than the melting point of the intermediate layer F2, particles of the ceramic thermal spray film F1 are melted and integrated with the surface of the intermediate layer F2, as shown in FIG. 9, (d), thereby providing a stronger bonding. The thermal spray will be explained later in detail.

Next, a detailed explanation will be given of a method for forming an intermediate layer F2 on a surface of a matrix 101 treated by a surface roughening process. In this embodiment, an Al₂O₃ film, which is a compound containing aluminum (Al), is formed as an example of an intermediate layer F2.

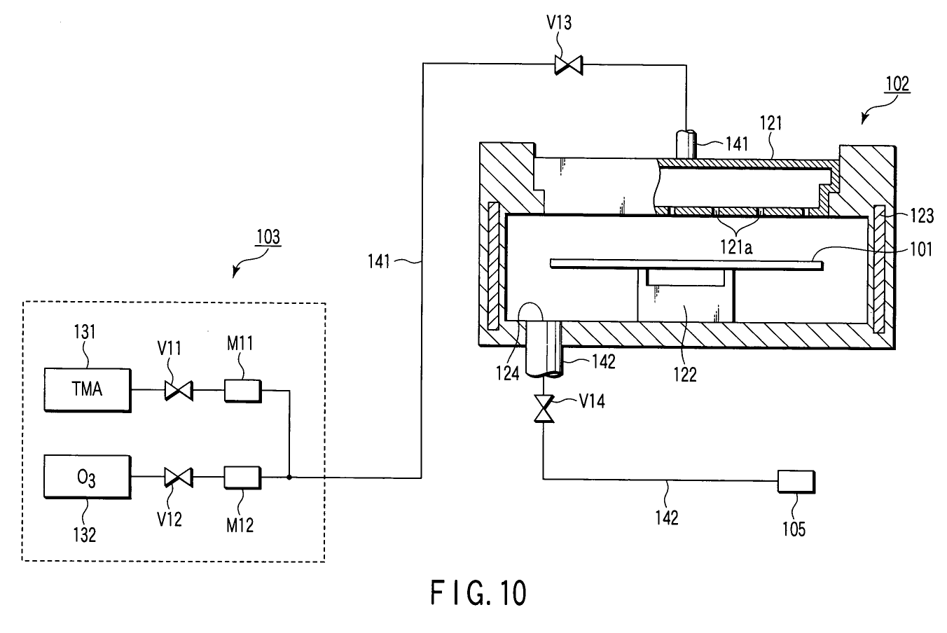

FIG. 10 is a structural view showing a film formation apparatus according to the second embodiment of the present invention, for forming an intermediate layer F2 on the surface of a matrix 101. The film formation apparatus includes a gas supply portion 103 for supplying gases used as source materials of the intermediate layer F2, a film formation container 102 for processing the matrix 101, and a vacuum pump 105. The gas supply portion 103 is connected to the film formation container 102 through a source material supply passage 141 provided with a switching valve V13. The film formation container 102 is connected to the vacuum pump 105 through a source material exhaust passage 142 provided with a switching valve V14.

The gas supply portion 103 includes a supply source (first source gas supply source 131) provided with a gasification mechanism for trimethyl aluminum (TMA: Al(CH₃)₃) used as a first source gas, and a supply source (second source gas supply source 132) of ozone (O₃) gas used as a second source gas. The first source gas supply source 131 is connected to a switching valve V11 and a mass-flow controller M11 in this order to supply the first source gas at a set flow rate. The second source gas supply source 132 is also connected to a switching valve V12 and a mass-flow controller M12 for the same purpose.

The film formation container 102 is a reaction container used for forming the intermediate layer F2 on a surface of the matrix 101 (the surface of the matrix 101 that comes in contact with a corrosive gas or plasma). For example, the film formation container 102 is made of a metal material, the internal surface of which is coated with a ceramic thermal spray film. The film formation container 102 is provided with a gas feed portion 121 made of, e.g., the same material, a support table 122, a tape heater 123, and an exhaust port 124.

The gas feed portion 121 serves as a supply port to deliver the source gases supplied from a gas supply portion 103. The gas feed portion 121 is located on an upper side within the film formation container 102, and is connected to the gas supply portion 103 through the source material supply passage 141. For example, the gas feed portion 121 includes a bottom surface with a number of source gas feed holes 121a formed therein, so that the source gases are uniformly supplied into the film formation container 102 without flow deviation.

The support table 122 is arranged to place thereon the matrix 101, on which the intermediate layer F2 is to be formed. The support table 122 is located on a lower side within the film formation container 102, and is set, e.g., to face the gas feed portion 121. Consequently, the source gases are supplied from the gas feed portion 121 and comes into contact with the surface of the matrix 101. The surfaces of the gas feed portion 121 and support table 122 that come in contact with the source gases are made of, e.g., aluminum.

The tape heater 123 serves to heat the interior of the film formation container 102 to a reaction temperature of the source gases. The tape heater 123 is formed of, e.g., a tape-like resistive heating body, and is embedded in the sidewall or the like of the film formation container 102. The exhaust port 124 serves as a port for exhausting the source gases from inside the film formation container 102. The exhaust port 124 is formed in, e.g., the bottom of the film formation container 102, and is connected to the vacuum pump 105 through the source material exhaust passage 142.

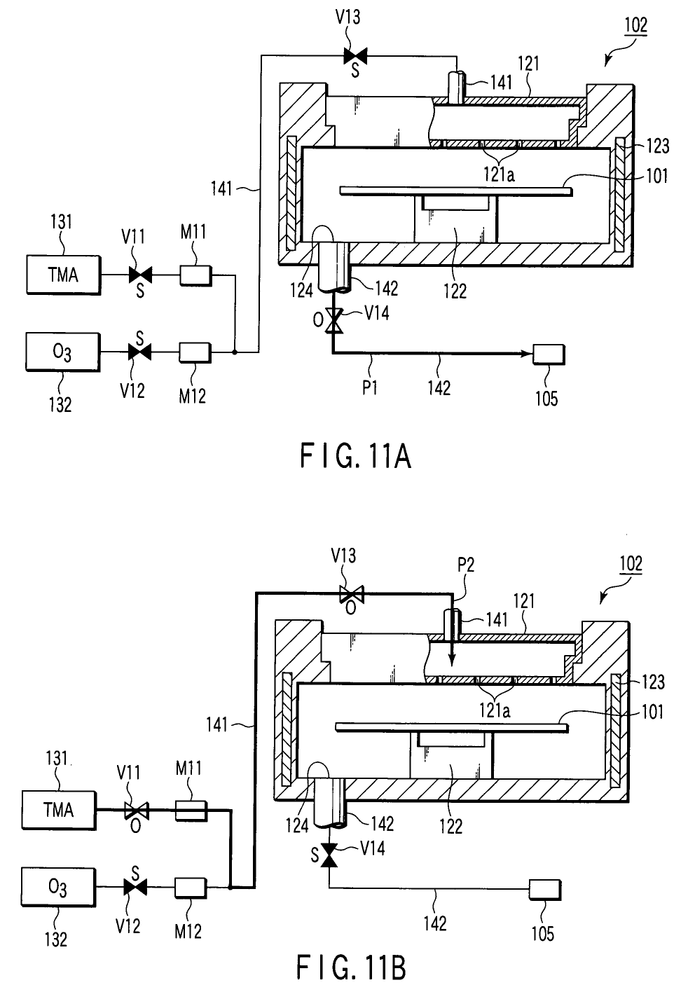

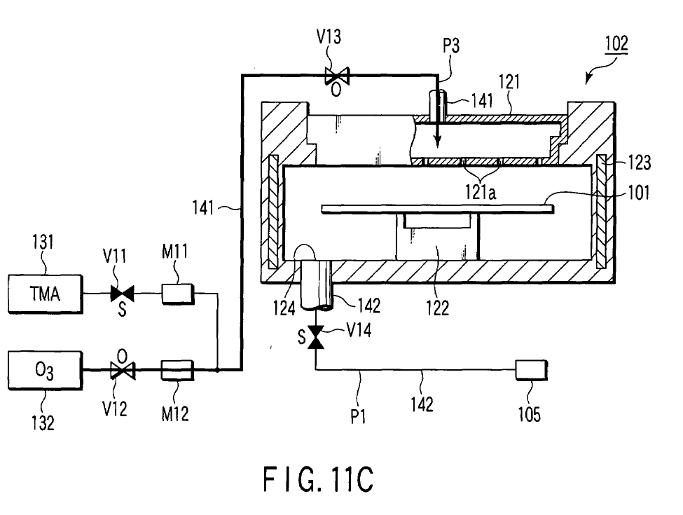

Then, an explanation will be given of a method for forming an intermediate layer (ALD film) F₂ by use of a film formation apparatus with reference to FIGS. 11A, 11B, 11C, and 12. FIGS. 11A, 11B, and 11C are views each showing a state of the film formation apparatus in a step of a process for forming the intermediate layer F2 (the open/closed state of valves and the routes of source gases flowing through the apparatus). Valves in the open state are marked with the letter “O”, while valves in the closed state are blackened and marked with the letter “S”.

FIG. 11A shows a state of the apparatus used when a source gas is exhausted from inside the film formation container 102. At this time, the valves V11, V12, and V13 are set in the closed state to stop supply of the source gases into the film formation container 102. Further, the valve V14 is set in the open state, so that a source gas is exhausted from inside the film formation container 102 to the vacuum pump 105 through a route P1.

FIG. 11B shows a state of the apparatus used when the first source gas or TMA gas is supplied into the film formation container 102. At this time, the valve V12 is set in the closed state to stop supply of O₃ gas. Further, the valve V14 is set in the closed state to close the exhaust port 124 of the film formation container 102. Then, the valves V11 and V13 are set in the open state, so that TMA gas is supplied from the first source gas supply source 131 into the film formation container 102 through a route P2.

FIG. 11C shows a state of the apparatus used when the second source gas or O₃ gas is supplied into the film formation container 102. At this time, the valve V11 is set in the closed state to stop supply of TMA gas. Further, the valve V14 is set in the closed state to close the exhaust port 124 of the film formation container 102. Then, the valves V12 and V13 are set in the open state, so that O₃ gas is supplied from the second source gas supply source 132 into the film formation container 102 through a route P3.

Then, a film formation step of the intermediate layer F2 according to this embodiment will be explained. FIG. 12 is a flowchart showing a film formation process of the intermediate layer F2. At first, the process target object or matrix 101 is placed on the support table 122 inside the film formation container 102. Then, the surface of the matrix is heated by the tape heater 123 to, e.g., about 150° C. Further, the interior of the film formation container 102 is vacuum-exhausted by the vacuum pump 105 to, e.g., about 133 Pa (1 Torr) (Step S21).

Then, the first source gas or TMA gas is supplied into the film formation container 102 at a flow rate of, e.g., about 100 ml/min for 1 second. Consequently, TMA gas is adsorbed on the surface of the process target object or matrix 101 (Step S22).

Then, the interior of the film formation container 102 is vacuum-exhausted for about 2 seconds (Step S23). Consequently, the residual part of the first source gas, which is not adsorbed on the matrix surface and thus is suspended inside the film formation container 102, is exhausted. Then, the second source gas or O₃ gas is supplied into the film formation container 102 at a flow rate of, e.g., about 1,000 ml/min for about 1 second. The O₃ gas reacts with TMA adsorbed on the matrix 101, and thereby generates an aluminum oxide (alumina in a solid phase) that is expressed by a chemical formula of Al₂O₃. Consequently, a very thin film made of Al₂O₃ is formed to have a film thickness of, e.g., about 3 nm (Step S24). When the interior of the film formation container 102 is vacuum-exhausted in Step S23, the pressure inside the film formation container 102 may be set higher than that described above. In this case, the amount of TMA gas adsorbed on the matrix 101 is increased, so a film thickness formed by one reaction becomes larger. Contrary, the pressure inside the film formation container 102 may be set lower than that described above, so that a film thickness formed by one reaction becomes smaller.

Then, the interior of the film formation container 102 is vacuum-exhausted for about 2 seconds to exhaust the residual part of O₃ gas (Step S25). The Steps S22 to S25 are repeated, e.g., several dozen times, so that an intermediate layer F2 is formed to have a film thickness of, e.g., about 100 nm (Step S26).

As described above, according to this embodiment, a matrix 101 set as a process target object is first exposed to a first source gas atmosphere, so the first source gas is adsorbed on the surface of the matrix 101. Then, this atmosphere is switched to a second source gas atmosphere that reacts with the first source gas. Consequently, an Al₂O₃ molecular layer is formed to have a film thickness of, e.g., about 3 nm. The atmospheres to which the matrix is exposed are alternately switched a number of times between the first source gas atmosphere and second source gas atmosphere. A plurality of aluminum oxide layers having an atomic or molecular level thickness thus formed are laminated on the surface of the matrix 101, so an intermediate layer F2 is formed from the aluminum oxide layers. In the film formation apparatus shown in FIG. 10, the interior of the film formation container 102 is heated by the tape heater 123. However, since the reaction between TMA and O₃ can proceed at a temperature of, e.g., from about room temperature to 200° C., heating by the tape heater 123 is not necessarily required.

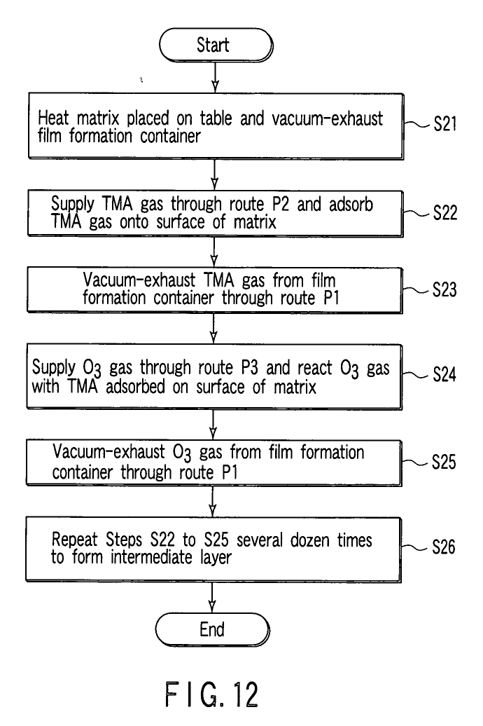

FIG. 13 is a timing chart showing supply of source gases relative to a film formation apparatus. As shown in FIG. 13, TMA gas and O₃ gas are alternately supplied into the film formation container 102. Further, during each of the periods (period of t12 to t13 and period of t14 to t15) between the gas supply periods, the interior of the film formation container 102 is vacuum-exhausted for, e.g., 2 seconds. Consequently, a very thin Al₂O₃ film is formed on the surface of the matrix 101 inside the film formation container 102. One cycle formed of the steps between times t11 to t15 is repeated, e.g., several dozen times, so that an intermediate layer consisting of Al₂O₃ films is formed to have a film thickness of, e.g., 100 nm on the surface of the matrix 101.

The intermediate layer formed by a film formation method according to this embodiment is not limited to an Al₂O₃ film formed by a reaction between TMA and O₃ described above. The intermediate layer may be made of an oxide of an element selected from the group consisting of aluminum, silicon, zirconium, yttrium, and hafnium (these elements will be referred to as “specific element group”).

In this respect, specific examples are as follows. A first source gas comprising Al(T-OC₄H₉)₃ gas and a second source gas comprising H₂O gas are used to form Al₂O₃. A first source gas comprising TEOS gas and a second source gas comprising O₃ gas are used to form SiO₂. A first source gas comprising ZrCl₄ gas and a second source gas comprising O₃ gas are used to form ZrO₂. A first source gas comprising Zr(T-OC₄H₉)₄ gas and a second source gas comprising O₃ gas are used to form ZrO₂. A first source gas comprising YCl₃ gas and a second source gas comprising O₃ gas are used to form Y₂O₃. A first source gas comprising Y(C₅H₅)₃ gas and a second source gas comprising O₃ gas are used to form Y₂O₃. A first source gas comprising HfCl₄ gas and a second source gas comprising O₃ gas are used to form HfO₂. A first source gas comprising Hf(N(CH₃)(C₂H₅))₄ gas and a second source gas comprising O₃ gas are used to form HfO₂. A first source gas comprising Hf(N(C₂H₅)₂)₄ gas and a second source gas comprising O₃ gas are used to form HfO₂.

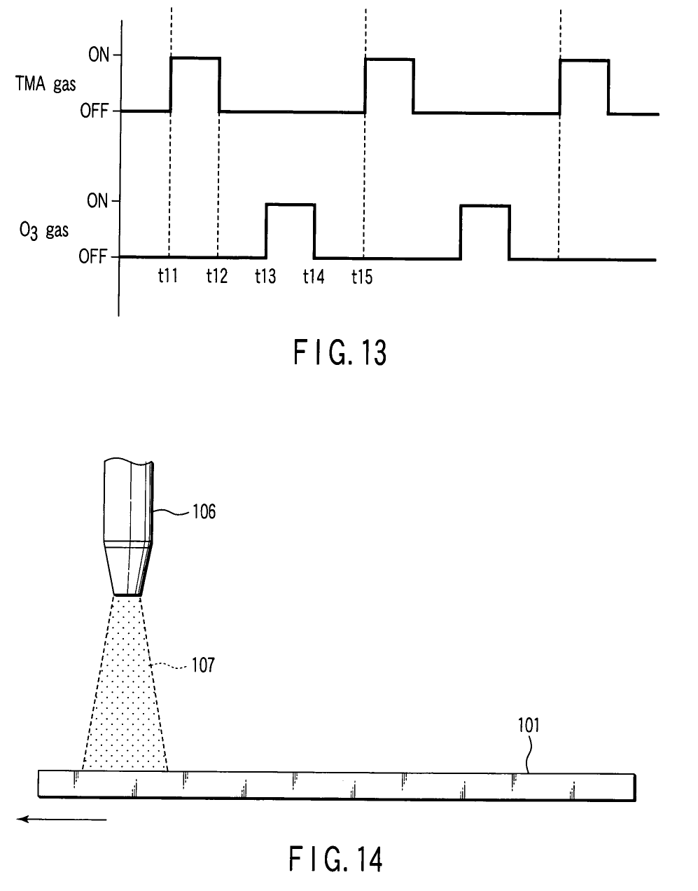

Next, a brief explanation will be given of a method for forming a ceramic thermal spray film F1 by thermal spray of a ceramic thermal spray material onto the surface of the matrix 101 having the intermediate layer F2 formed thereon. FIG. 14 is a side view showing a manner of applying molten droplets 107 by thermal spraying onto the surface of the matrix 101 having the intermediate layer F2 formed thereon. By way of example, FIG. 14 shows a thermal spray nozzle 106 of the Rokide rod spray type. The thermal spray nozzle 106 is arranged such that an Al₂O₃ sintered rod (not shown) pushed out to the nozzle portion is melted by heating at, e.g., 2,500° C. by use of, e.g., oxygen-acetylene flame, and molten droplets 107 thus obtained are sprayed toward the matrix 101 by use of an air jet. The matrix 101 is moved by a shifting mechanism (not shown), so that the molten droplets 107 are thermally sprayed all over the surface of the matrix 101. The molten droplets 107 thus thermally sprayed on the matrix surface solidifies and forms a ceramic thermal spray film F1 (made of poly-crystal) on the intermediate layer F2, thereby manufacturing an environment-proof member 110. The thermal spray method is not limited to the Rokide rod spray type, and it may be, e.g., the plasma powder spray type, arc spray type, or thermo spray type.

In general, the molten droplets 107 are thermally sprayed at a temperature higher than the melting point of Al₂O₃ in the thermal spray step, so the Al₂O₃ surface of the intermediate layer F2 on the matrix 101 is once melted and then solidified. Consequently, the ceramic thermal spray film F1 is integrated with the intermediate layer F2 to form a coating film with a strong bonding force. The thermal spray material selected for this thermal spray is not limited to Al₂O₃. The material of the intermediate layer F2 is an oxide (ceramic), such as SiO₂, ZrO₂, Y₂O₃, or HfO₂, which contains an element selected from the specific element group, in accordance with the environment to be applied to the environment-proof member 110. The ceramic thermal spray film F1 and intermediate layer F2 may be made of the same ceramic or different ceramics.

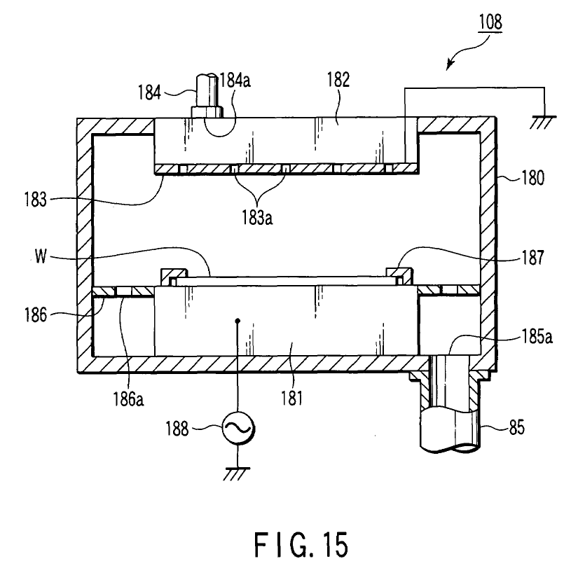

FIG. 15 is a sectional view showing a semiconductor processing apparatus according to the second embodiment of the present invention, in which an environment-proof member according to the present invention is used as a component. The apparatus shown in FIG. 15 is an etching apparatus 108 arranged to generate plasma therein so as to perform a plasma process step of etching a substrate or semiconductor wafer (which will be referred to as a wafer W). The etching apparatus 108 includes a process container 180 forming a vacuum chamber. A gas supply portion 182 is located inside the process container 180 and has a bottom member 183 serving as an upper electrode as well. Further, a worktable 181 for placing a wafer W thereon and serving as a lower electrode is located inside the process container 180 to face the gas supply portion 182. The worktable 181 is connected to an RF (radio frequency) power supply 188.

The process container 180 is connected to a process gas supply line 184 to supply a process gas through the gas supply portion 182. Further, the process container 180 is connected to a vacuum pump (not shown) through an exhaust line 185 to exhaust the process gas and thereby set the interior at a predetermined pressure. The worktable 181 of the etching apparatus 108 is surrounded by an exhaust ring 186 having, e.g., a plurality of gas exhaust holes 186a arrayed in an annular direction. The exhaust ring 186 allows gas inside the process container 180 to be exhausted from around worktable 181 essentially uniformly in an annular direction. In FIG. 15, there is a mechanical chuck 187 configured to mechanically press the periphery of the wafer W to hold this wafer W on the worktable 181.

The bottom member 183 of the gas supply portion (gas showerhead) 182 has a number of gas holes 183a formed therein. A predetermined process gas selected in accordance with the process type is delivered from the gas holes 183a onto the wafer W on the worktable 181. While the process gas is supplied and the vacuum pump is operated for vacuum exhaust, a radio frequency voltage is applied between the upper and lower electrodes from the radio frequency power supply 188. Consequently, the process gas is turned into plasma, thereby performing etching on the wafer W.

In this etching apparatus 108, components each formed of an environment-proof member 110 according to this embodiment are components located inside the process container 10 and having a surface that comes in contact with plasma, such as the bottom member 183 of the gas supply portion 182, the exhaust ring 186, and the mechanical chuck 187. FIG. 15 shows the etching apparatus 108 arranged to perform a plasma process step as an example of this embodiment, but a component formed of an environment-proof member 110 may be used in a semiconductor manufacturing apparatus other than this apparatus. For example, an environment-proof member 110 according to this embodiment may be applied to a component used in a film formation apparatus arranged to use a corrosive gas to perform a film formation process on a wafer W, or a film formation apparatus arranged to use a corrosive gas to perform cleaning for, e.g., the interior of a film formation container. Further, a component of this type may be used in a semiconductor manufacturing apparatus other than the examples described above.

For example, an environment-proof member 110 of this type is manufactured by a component maker. A semiconductor apparatus maker purchases the component and sets it in an etching apparatus, i.e., sets it as a component of a semiconductor manufacturing apparatus. Alternatively, in a maintenance operation performed periodically or as needed for a semiconductor manufacturing apparatus, a component to be reprocessed is detached from the semiconductor manufacturing apparatus. Then, this component is subjected to a formation process of the intermediate layer F2 and a thermal spray process. The environment-proof member 110 thus reproduced is attached to the semiconductor manufacturing apparatus.

In an environment-proof member 110 according to this embodiment, since the matrix surface is covered with a dense coating formed of the intermediate layer F2, a corrosive gas or plasma passing through pores of the ceramic thermal spray film F1 can hardly reach the matrix surface. Further, the intermediate layer F2 is made of an oxide (ceramic) containing an element selected from the specific element group, and thus has a property resistant to a corrosive gas or plasma. Consequently, the environment-proof property of the environment-proof member 110 against corrosion and/or damage is improved for use in an environment in which the component is exposed to a corrosive gas or plasma, as compared to a case where the ceramic thermal spray film F1 is formed directly on the matrix surface. Further, an environment-proof member 110 using a matrix 101 made of aluminum or stainless steel, which is relatively lower in price and better in machinability than ceramics, can be used for a long time, because the environment-proof property thereof has been improved.

According to this embodiment, since an intermediate layer F2 made of a ceramic (an oxide of an element of the specific element group) is formed by a reaction of two source gases caused on a matrix surface, the intermediate layer F2 coheres with the matrix surface densely at a molecular level. Consequently, even where the matrix 101 and intermediate layer F2 are made of materials that cannot be bonded to each other by a chemical bonding force or the like, an environment-proof member 110 is prepared such that the intermediate layer F2 can hardly peel off the matrix surface.

In general, the ceramic thermal spray film F1 is thermally sprayed at a temperature higher than the melting point of the oxide (ceramic) layer forming the intermediate layer F2. Consequently, the ceramic thermal spray film F1 is melted and integrated with the intermediate layer F2 to form a coating film with a strong bonding force. In this case, the intermediate layer F2 serves as an anchor to improve the environment-proof member 110 such that the ceramic thermal spray film F1 can hardly peel off. Particularly, the materials of the ceramic thermal spray film F1 and intermediate layer F2 can be oxides of elements suitably selected from the specific element group, such as the same ceramic. In this case, the melting points of the ceramic thermal spray film F1 and intermediate layer F2 are relatively close to or the same as each other, and thus the films can be integrated more easily.

Further, where the ceramic thermal spray film F1 is formed on the surface of the intermediate layer F2, a very thick coating film can be formed in a short time. Consequently, the cost for manufacturing the environment-proof member 110 can be decreased, as compared to a case where an intermediate layer F2 is deposited to the same thickness as the ceramic thermal spray film F1.

Next, a modification of the second embodiment will be explained. The example described above according to the second embodiment is directed to a method for performing a surface preparation on a plate-like member or block-like member. On the other hand, the modification of this second embodiment is directed to a surface preparation performed on the internal surface of a pipe member.

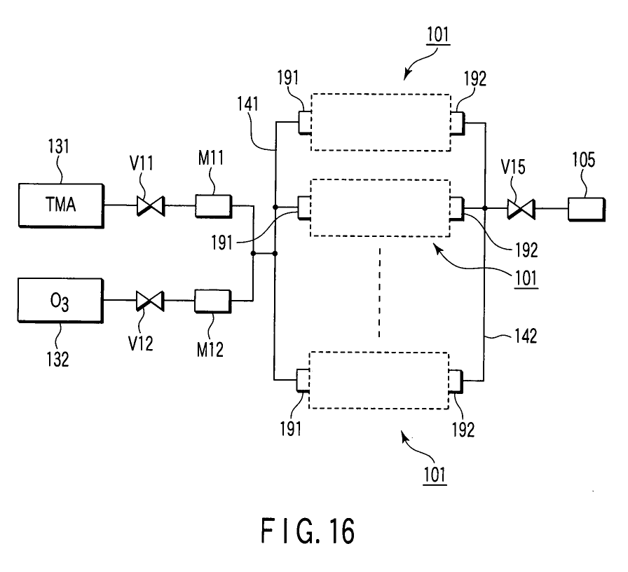

FIG. 16 is a structural view showing a film formation apparatus according to a modification of the second embodiment of the present invention. This film formation apparatus differs from the apparatus shown in FIG. 10, such that a plurality of gas pipes are connected in parallel and each provided with a pair of connector members 191 and 192, between which a pipe matrix 101 set as a process target object is to be connected. Specifically, as shown in FIG. 16, a source material supply passage 141 branches into a plurality of pipes, which are respectively connected to connector members 191 on the supply side. Similarly, a source material exhaust passage 142 branches into a plurality of pipes, which are respectively connected to connector members 192 on the exhaust side.

For example, the matrix 101 set as a process target object is a pipe member of a semiconductor manufacturing apparatus, which has an internal surface that comes in contact with a corrosive gas or plasma. A tape heater may be wound around the external surface of a component (matrix 101) connected between the connector members 191 and 192, so as to heat the surface of the matrix 101 on which an intermediate layer F2 is to be formed.

After the matrix 101 is connected between the connector members 191 and 192, supply of the first and second source gases and vacuum exhaust relative to the interior of the matrix are repeated in the same method as explained with reference to FIGS. 11A to 13. Consequently, an intermediate layer F2 is formed on the surface of the matrix 101 (the internal surface of the component). Then, a ceramic thermal spray film F1 is thermally sprayed. The material of the intermediate layer F2 formed on the matrix 101 will be not explained, because it is the same as that defined in the embodiment described above.

The second embodiment has been explained with reference to a case where an intermediate layer F2 is formed on a metal material, such as aluminum or stainless steel, but the material of a matrix 101 for an environment-proof member 110 according to this embodiment is not limited to this example. For example, in accordance with the intended use, a process may be arranged such that an intermediate layer F2 is formed on a matrix 101 made of a ceramic, such as silica, by the method described above, and then a ceramic thermal spray film F1 is formed on the intermediate layer F2. Some of the ceramics have poor wettability, depending on the material. Where a ceramic thermal spray film F1 is formed directly on the surface of such a matrix 101, the thermal spray film cannot intrude into minute recesses on the matrix. In this case, the ceramic thermal spray film F1 peels off more easily as compared to a metal matrix 101. On the other hand, the intermediate layer F2 formed by a method according to this embodiment coheres with the matrix surface at a molecular level as described previously. In this case, the film can hardly peel off the ceramic matrix 101 without reference to the wettability. Consequently, even where the matrix 101 is made of a ceramic, the intermediate layer F2 can serve as an anchor and an environment-proof member 110 is thereby prepared such that the ceramic thermal spray film F1 can hardly peel off.

### Third Embodiment

According to a third embodiment, after a semiconductor processing apparatus is assembled, first and second source gases for forming an ALD film are supplied to perform an ALD process on an area where a corrosive gas flows through. Consequently, an ALD film (protection film) is formed on the surface of a metal component that comes in contact with a corrosive gas within an area where a corrosive gas flows through, so at to improve the corrosion resistance of the component relative to the corrosive gas. Examples of the semiconductor manufacturing apparatus encompass not only an apparatus for manufacturing semiconductor devices but also an apparatus for manufacturing flat panel displays. The semiconductor manufacturing apparatus may be an apparatus arranged to use a corrosive gas as a process gas, an apparatus arranged to supply a corrosive gas used as a cleaning gas into a process container to perform cleaning for the interior of the process container after a substrate process, or an apparatus arranged to perform a process by use of plasma. Specifically, an etching apparatus, film formation apparatus, or ashing apparatus corresponds to this definition.

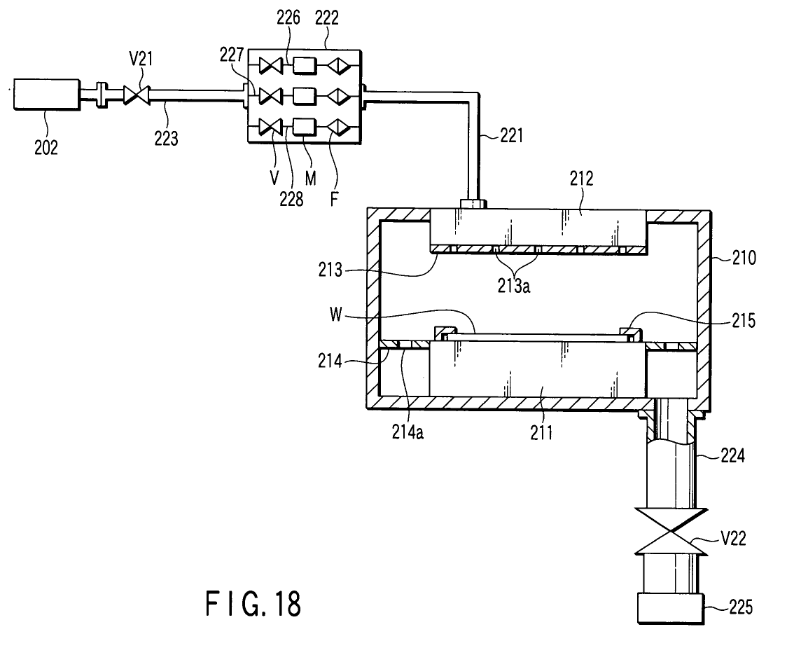

FIG. 18 is a sectional view showing a semiconductor processing apparatus according to the third embodiment of the present invention. In this apparatus, a wafer W is placed on a worktable 211 located inside a process container 210. A gas supply portion (gas showerhead) 212 is disposed to face the worktable 211 inside the process container 210. The showerhead 212 includes a bottom member 213 with a number of gas holes 213a formed therein, through which a process gas or cleaning gas of, e.g., a corrosive gas, is supplied onto the wafer W on the worktable 211.

The worktable 211 is surrounded by a baffle plate 214 having, e.g., a plurality of gas exhaust ports 214a. The baffle plate 214 allows gas inside the process container 210 to be exhausted from around worktable 211 essentially uniformly in an annular direction. In FIG. 18, there is a mechanical chuck 215 configured to mechanically press the periphery of the wafer W to hold this wafer W on the worktable 211.

The gas supply portion 212 is connected to a process gas supply pipe 221 attached to this process container. The process gas supply pipe 221 is connected to a gas supply unit 222. The upstream side of the process gas supply pipe 221 is connected through a gas pipe 223 provided with a valve V21 to a supply source 202 of a process gas or corrosive gas, on the user side, as described later. Further, the process container 210 is connected through an exhaust pipe 224 provided with a valve V22 to vacuum exhaust means, such as a vacuum pump 225, to exhaust the interior of the process container 210. In this embodiment, the process gas supply pipe 221 and gas pipe 223 constitutes a line for supplying a corrosive gas into the process container 210.

The gas supply unit 222 is a unit combining various pipes, measuring devices, and so forth connected to the process gas supply pipe 221 and gas pipe 223. These members include gas pipes 226 to 228 for various gases, such as a process gas and a corrosive gas, and valves V, mass-flow controllers M, and filters F connected to these gas pipes 226 to 228.

Some components are manufactured by the maker of manufacturing the semiconductor processing apparatus and are delivered to the user side. These components encompass the process container 210, components located inside the process container 210, the process gas supply pipe 221 and exhaust pipe 224 attached to the process container 210, and the vacuum pump 225. These components are delivered to the user side and assembled in the user side, so that they are connected through the gas pipe 223 to the gas supply source 202 both on the user side.

According to this embodiment, for example, a surface preparation is performed when a start-up operation or a periodical maintenance operation is performed on the semiconductor processing apparatus after the apparatus is assembled on the user side. This surface preparation is performed in a state where the process gas supply pipe 221 and gas pipe 223 are attached to the process container 210. For example, components set as surface preparation target objects are metal components used in an area where a corrosive gas flows through. An ALD film is formed by the surface preparation on the surface of these components that comes in contact with the corrosive gas. Specifically, for example, these components are metal components, such as the process container 210, the process gas supply pipe 221, the gas pipe 223, the exhaust pipe 224 for exhausting the interior of the process container 210, the valves V21 and V22 disposed on the pipes 223 and 224, the gas supply unit 222, the bottom member 213 of the gas supply portion (gas showerhead) 212, the baffle plate 214, and the mechanical chuck 215.

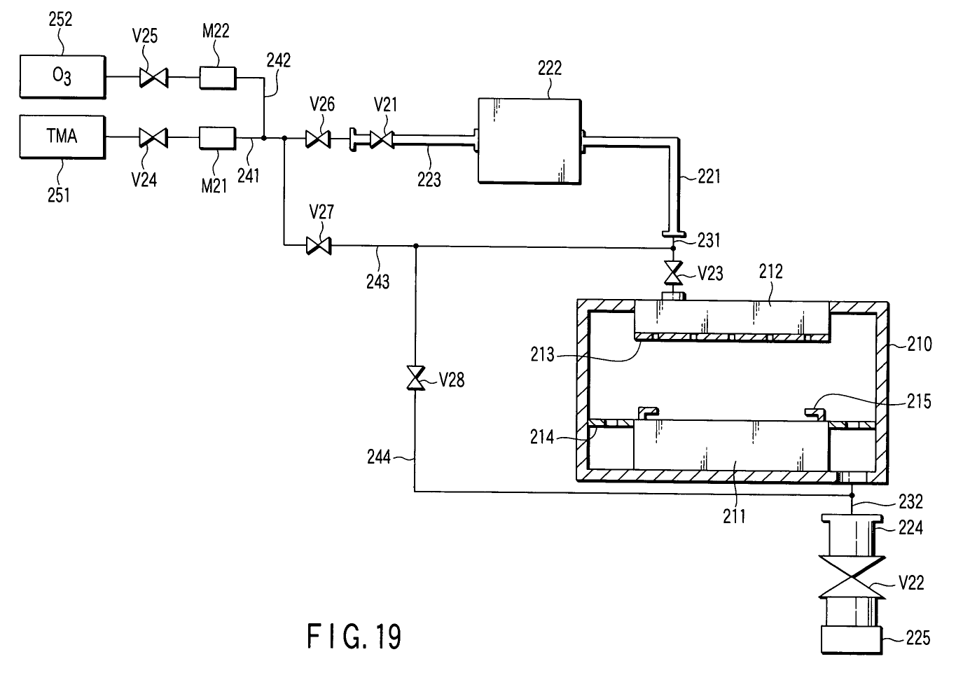

FIG. 19 is a structural view showing an example of a surface preparation apparatus according to the third embodiment of the present invention, arranged to perform a surface preparation for forming an ALD film on a component of a semiconductor processing apparatus. The following explanation will be exemplified by a case where a surface preparation is arranged to form an ALD film made of Al(T-OC₄H₉)₃, which is a compound containing aluminum (Al), on the surface of a metal component set as a surface preparation target object.

A process container 210 is connected to a gas supply unit 222 through a process gas supply pipe 221. The gas supply unit 222 is connected to a gas pipe 223 on the user side. Further, the process container 210 is connected to a vacuum pump 225 through an exhaust pipe 224 provided with a valve V22. A pipe 231 provided with a switching valve V23 for connecting a by-pass passage is connected between the process container 210 and process gas supply pipe 221. A pipe 232 for connecting a by-pass passage is also connected between the process container 210 and exhaust pipe 224.

The upstream side of the gas supply unit 222 is connected to a supply source (first source gas supply source) 251 of trimethyl amine (TMA: Al(CH₃)₃) used as a first source gas through a first source material supply passage 241 provided with a switching valve V24 and a mass-flow controller M21. Further, the unit 222 is connected to a supply source (second source gas supply source) 252 of ozone (O₃) gas used as a second source gas through a second source material supply passage 242 branched from the first source material supply passage 241 and provided with a switching valve V25 and a mass-flow controller M22. The first source gas supply source 251 includes a gasification mechanism for TMA.

The first source material supply passage 241 is provided with a switching valve V26 downstream from the connecting portion of the second source material supply passage 242, for controlling the on/off operation of supply of the source gases to the gas supply unit 222. Further, a first by-pass passage 243 provided with a switching valve V27 is connected between the switching valve V26 and the connecting portion of the first source material supply passage 241 and second source material supply passage 242. The other end of this first by-pass passage 243 is connected to the pipe 231 upstream from the switching valve V23. The first by-pass passage 243 is also connected to a second by-pass passage 244 provided with the switching valve V28, downstream from the switching valve V27. The other end of this second by-pass passage 244 is connected to the pipe 232.

The pipes 231 and 232, first and second source material supply passages 241 and 242, and first and second by-pass passages 243 and 244 are made of, e.g., stainless steel pipes. Further, where a surface preparation is performed while the process container 210 is connected through the pipes 231 and 232 to the process gas supply pipe 221, gas pipe 223, gas supply unit 222, and exhaust pipe 224, the process gas supply pipe 221, gas pipe 223, and exhaust pipe 224, are provided with heating means, such a tape heater, wound around them, as described later. Further, the gas supply unit 222 and process container 210 are provided with heating means, such as a resistive heating body, disposed around them.

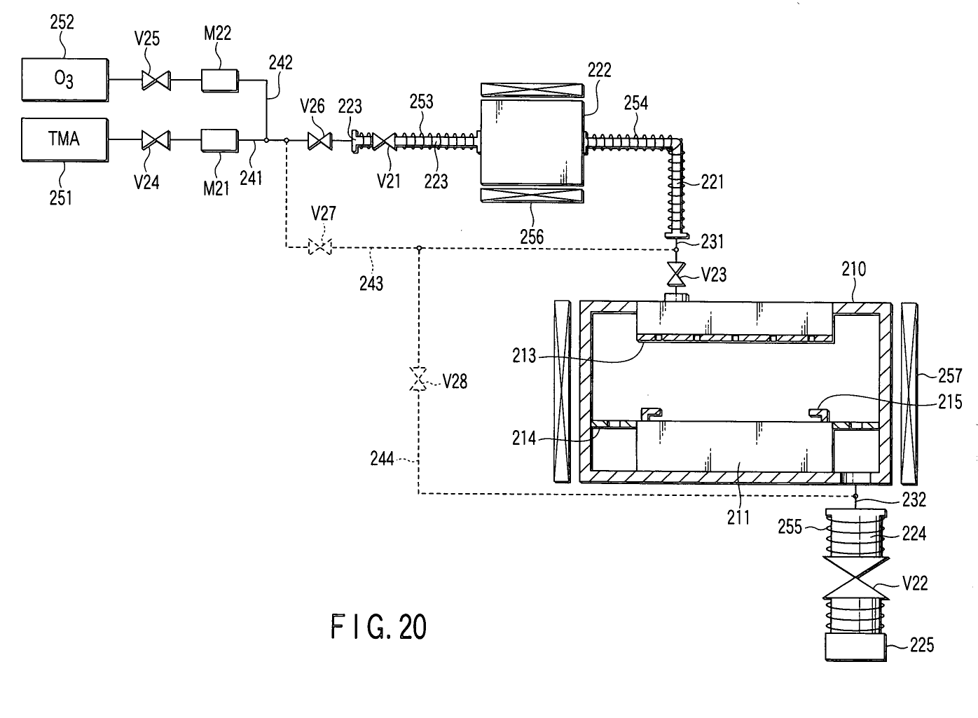

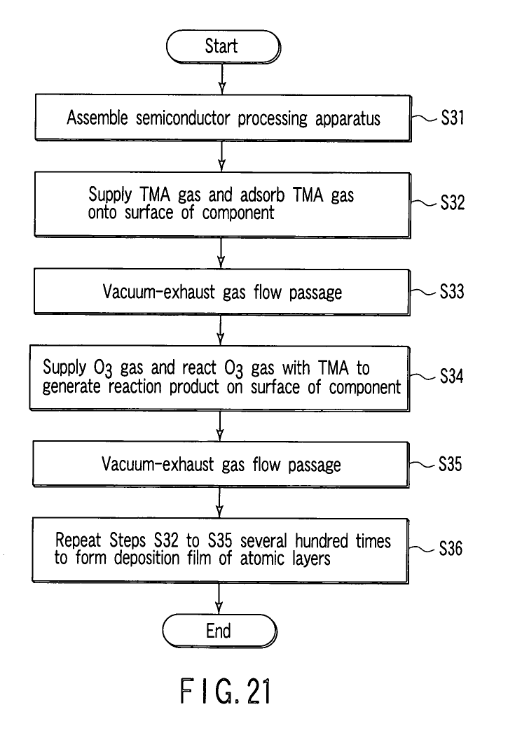

FIG. 20 is a structural view showing an arrangement for performing a surface preparation of a process container and a pipe for supplying a process gas into the process container, by the surface preparation apparatus shown in FIG. 19. FIG. 21 is a flowchart showing the process for performing the surface preparation of the process container and pipe, by the surface preparation apparatus shown in FIG. 19. For example, this surface preparation is performed after the apparatus manufactured on the maker side is delivered to the user side and is assembled on the user side. At first, an explanation will be given of a case where a surface preparation is performed together on the process container 210, process gas supply pipe 221, gas pipe 223, gas supply unit 222, and exhaust pipe 224.

For example, where each of the process gas supply pipe 221, gas pipe 223, and exhaust pipe 224 is formed of a metal matrix, such as stainless steel or aluminum, the surface preparation is performed to form a deposition film (protection film) on the surface of this metal matrix. For example, the matrix process container 210 is made of aluminum, or the surface thereof is covered with a thermal spray film (made of poly-crystal), such as an aluminum or yttria thermal spray film. Accordingly, a deposition film is formed on the surface of the matrix or the surface of the thermal spray film. For example, the thermal spray film is a film containing boron (B), magnesium (Mg), aluminum (Al), silicon (Si), gallium (Ga), chromium (Cr), yttrium (Y), zirconium (Zr), tantalum (Ta), germanium (Ge), or neodymium (Nd).

Further, according to this embodiment, a surface preparation is performed together on metal components located inside the process container 210, such as the bottom member 213 of the gas supply portion 212, the baffle plate 214, and the mechanical chuck 215. In this case, each of these components is formed of a metal matrix, such as stainless steel or aluminum, and a deposition film is formed on the surface of the matrix.

At first, the apparatus delivered from the maker side is assembled on the user side (Step S31). Specifically, as shown in FIG. 20, the process container 210 including internal metal components attached therein is connected to the process gas supply pipe 221, gas supply unit 222, gas pipe 223 through the pipe 231. Further, the process container 210 is connected to the exhaust pipe 224 and vacuum pump 225 through the pipe 232. The upstream side of the gas pipe 223 is connected to the first and second source gas supply sources 251 and 252, in place of the gas supply source 202, through the first and second source material flow passages 241 and 242. Further, as described above, the first and second by-pass passages 243 and 244 are connected.

By doing so, the apparatus is set in an assembled state. Specifically, in the assembled state of the apparatus, the process container 210 is connected directly or through the pipe 231 to the pipe used for connecting the gas supply source 202 and process container 210, and the gas supply unit 222 disposed on this pipe. Further, the process container 210 is connected directly or through the pipe 232 to the exhaust pipe 224 and vacuum pump 225. At this time, the gas supply unit 222 is set such that the corrosive gas pipe 227 is connected to the gas pipe 223 and process gas supply pipe 221, and the valve V of this pipe 227 is opened.

For example, the gas pipe 223, process gas supply pipe 221, exhaust pipe 224 are provided with heating means 253, 254, and 255 formed of a tape heater wound around them. Further, the gas supply unit 222 and process container 210 are provided with heating means 256 and 257 formed of a resistive heating body disposed around them. Consequently, the surface of each component that comes in contact with the source gases within an area where the source gases flow through is heated to, e.g., about 150° C.

Then, the valves V21, V22, and V23 are opened, and the valves V24, V25, V26, V27, and V28 are closed. In this state, the interior of a gas flow passage extending from the gas pipe 223 through the gas supply unit 222, process gas supply pipe 221, and process container 210 to the exhaust pipe 224 is vacuum-exhausted by the vacuum pump 225 to, e.g., about 133 Pa (1 Torr).

Then, the valve V22 is closed, the valves V24 and V26 are opened, and the first source gas or TMA gas is supplied into the gas flow passage at a flow rate of, e.g., about 100 ml/min for about 1 second. Consequently, TMA gas is adsorbed on the surface of components located inside the gas flow passage (area where a corrosive gas flows through) (Step S32). Specifically, for example, TMA gas is adsorbed on the internal surface of the gas pipe 223, gas supply unit 222, process gas supply pipe 221, process container 210, and exhaust pipe 224, and the surface of components located inside the process container 210.

Then, the valves V24 and V26 are closed, the valve V22 is opened, and the interior of the gas flow passage is vacuum-exhausted for about 2 seconds (Step S33). Consequently, the residual part of the first source gas, which is not adsorbed on the surface of components located inside the gas flow passage and thus is suspended inside the gas flow passage, is exhausted.

Then, the valve V22 is closed, the valves V25 and V26 are opened, and the second source gas or O₃ gas is supplied into the gas flow passage at a flow rate of, e.g., about 100 ml/min for about 1 second. The O₃ gas reacts with liquid TMA adsorbed on the surface of components located inside the gas flow passage, and thereby generates a reaction product (in a solid phase) that is expressed by a chemical formula of Al₂O₃. Consequently, a very thin deposition film made of Al₂O₃ is formed to have a film thickness of, e.g., about 0.1 nm (Step S34). This thin deposition film is formed of an Al oxide layer.

Then, the valves V25 and V26 are closed, the valve V22 is opened, and the interior of the gas flow passage is vacuum-exhausted for about 2 seconds to exhaust the residual part of O₃ gas (Step S35). The Steps S32 to S35 are repeated, e.g., several hundred times, so that a deposition film is formed to have a thickness of, e.g., 20 nm on the surface of components located inside the gas flow passage (Step S36).

As described above, according to this embodiment, the interior of the gas flow passage set as a surface preparation target object is first exposed to a first source gas atmosphere, so the first source gas is adsorbed on the surface of components located inside the gas flow passage. Then, this atmosphere is switched to a second source gas atmosphere that reacts with the first source gas. Consequently, an Al atomic layer or Al-containing molecular layer is formed to have a film thickness of, e.g., about 0.1 nm. The interior of the gas flow passage is alternately switched a number of times between the first source gas atmosphere and second source gas atmosphere. Further, between the gas supply steps, steps of stopping the source gases and performing vacuum exhaust are respectively interposed. A deposition film thus formed by laminating a number of layers on the surface of a matrix is called an ALD (Atomic Layer Deposition) film, and this formation method is called an ALD method.

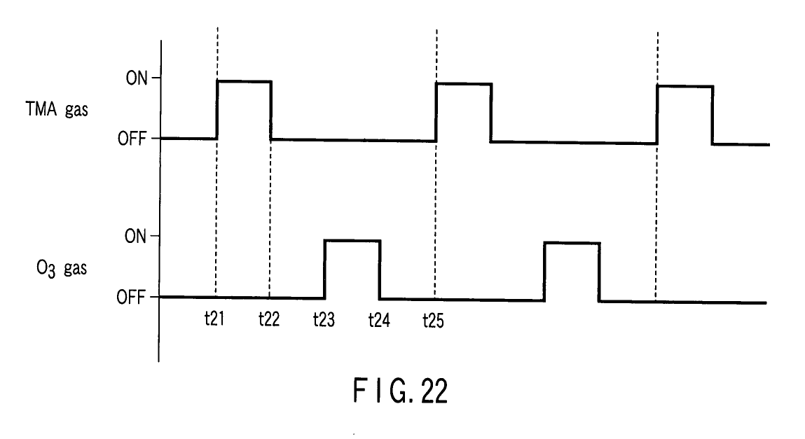

FIG. 22 is a timing chart showing supply of source gases for forming an ALD film on a process container and a pipe. As shown in FIG. 22, TMA gas and O₃ gas are alternately supplied into a gas flow passage. Further, during each of the periods (period of t22 to t23 and period of t24 to t25) between the gas supply periods, the interior of the gas flow passage is exhausted at full load for, e.g., 2 seconds. Consequently, a very thin Al₂O₃ film is formed on the internal surface of the gas flow passage and the surface of components located inside the gas flow passage. One cycle formed of the steps between times t21 to t25 is repeated, e.g., several hundred times, so that an ALD film consisting of Al₂O₃ films is formed to have a film thickness of, e.g., 20 nm on the internal surface of the gas flow passage and the surface of components located inside the gas flow passage.

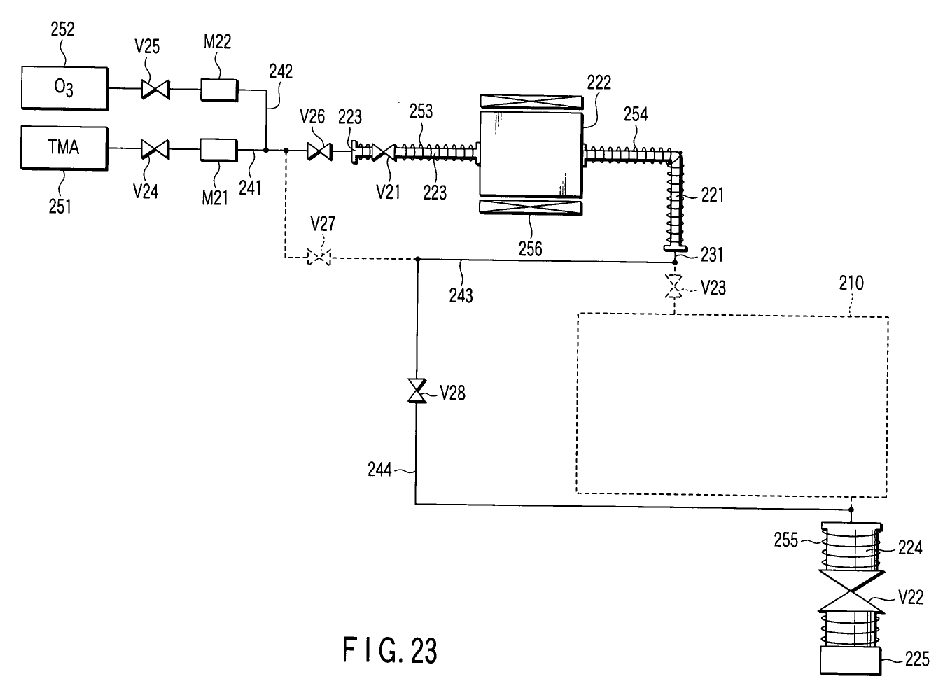

FIG. 23 is a structural view showing an arrangement for performing a surface preparation only of a pipe for supplying a process gas into a process container, by the surface preparation apparatus shown in FIG. 19. Specifically, a surface preparation is performed for the pipe connecting the gas supply source 202 to the process container 210 and the gas supply unit 222 disposed on this pipe, but no surface preparation is performed for the process container 210. In this case, for example, the first and second by-pass passages 243 and 244 are used to by-pass the process container 210, and allow the first and second source gases to flow therethrough. Further, the interior of the gas flow passage thus formed is set in a vacuum atmosphere. In this state, a surface preparation is performed for the gas flow passage extending from the gas pipe 223 through the gas supply instruments 222 and process gas supply pipe 221 to the exhaust pipe 224.

Also in this case, at first, the apparatus delivered from the maker side is assembled on the user side (Step S41), as described with reference to FIG. 19. Then, the internal surface of the gas pipe 223, process gas supply pipe 221, gas supply instruments 222, and exhaust pipe 224 are heated by, e.g., the heating means 253, 254, 255, and 256, respectively, to, e.g., about 150° C.

Then, the valves V21, V22, and V28 are opened, and the valves V23, V24, V25, V26, and V27 are closed. In this state, the interior of a gas flow passage extending from the gas pipe 223 through the gas supply unit 222 and process gas supply pipe 221 to the exhaust pipe 224 is vacuum-exhausted through the first and second by-pass flow passages 243 and 244 by the vacuum pump 225.

Then, the valves V22 and V28 are closed, the valves V24 and V26 are opened, and the first source gas or TMA gas is supplied into the gas flow passage at a flow rate of, e.g., about 100 ml/min for about 1 second. Consequently, TMA gas is adsorbed on the internal surface of the gas flow passage (Step S42). Then, the valves V24 and V26 are closed, the valves V22 and V28 are opened, and the interior of the gas flow passage is vacuum-exhausted for about 2 seconds (Step S43). Consequently, the residual part of the first source gas inside the gas flow passage is exhausted.

Then, the valves V22 and V28 are closed, the valves V25 and V26 are opened, and the second source gas or O₃ gas is supplied into the gas flow passage at a flow rate of, e.g., about 100 ml/min for about 1 second. The O₃ gas reacts with TMA adsorbed on the internal surface of the gas flow passage, and thereby forms a very thin deposition film made of Al₂O₃ (Step S44). Then, the valves V25 and V26 are closed, the valves V22 and V28 are opened, and the interior of the gas flow passage is vacuum-exhausted for about 2 seconds (Step S45). Consequently, the residual part of O₃ gas inside the gas flow passage is exhausted. The Steps S42 to S45 are repeated, e.g., several hundred times, so that a deposition film is formed on the internal surface of the gas pipe 223, the corrosive gas flow passage of the gas supply unit 222, the process gas supply pipe 221, and the exhaust pipe 224 (Step S46).

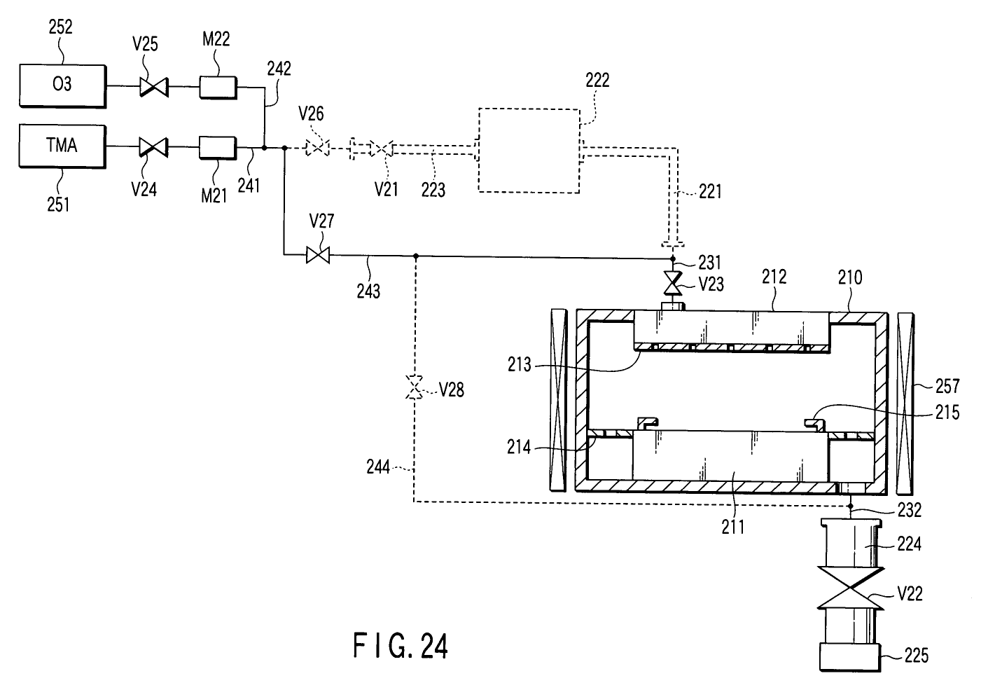

FIG. 24 is a structural view showing an arrangement for performing a surface preparation only of a process container, by the surface preparation apparatus shown in FIG. 19. In this case, the first by-pass passage 243 is used to by-pass the gas pipe 223, process gas supply pipe 221, and gas supply unit 222, and allows the first and second source gases to flow therethrough. Further, the interior of the gas flow passage thus formed is set in a vacuum atmosphere. In this state, a surface preparation is performed for the gas flow passage extending from the process container 210 to the exhaust pipe 224.

Also in this case, at first, the apparatus delivered from the maker side is assembled on the user side (Step S51), as described with reference to FIG. 19. Then, the interior of the process container 210 is heated by, e.g., the heating means 257 to, e.g., about 150° C.

Then, the valve V22 is opened, and the valves V21, V23, V24, V25, V26, V27, and V28 are closed. In this state, the interior of the process container 210 is vacuum-exhausted through by the vacuum pump 225.

Then, the valve V22 is closed, the valves V23, V24, and V27 are opened, and the first source gas or TMA gas is supplied into the gas flow passage at a flow rate of, e.g., about 100 ml/min for about 1 second. Consequently, TMA gas is adsorbed on the internal surface of the gas flow passage (Step S52). Then, the valves V23, V24, and V27 are closed, the valve V22 is opened, and the interior of the gas flow passage is vacuum-exhausted for about 2 seconds (Step S53). Consequently, the residual part of the first source gas inside the gas flow passage is exhausted.

Then, the valve V22 is closed, the valves V23, V25, and V27 are opened, and the second source gas or O₃ gas is supplied into the gas flow passage at a flow rate of, e.g., about 100 ml/min for about 1 second. The O₃ gas reacts with TMA adsorbed on the internal surface of the gas flow passage, and thereby forms a very thin deposition film made of Al₂O₃ (Step S54). Then, the valves V23, V25, and V27 are closed, the valve V22 is opened, and the interior of the gas flow passage is vacuum-exhausted for about 2 seconds (Step S55). Consequently, the residual part of O₃ gas inside the gas flow passage is exhausted. The Steps S52 to S55 are repeated, e.g., several hundred times, so that a deposition film is formed on the internal surface of the process container 210, the surface of components located inside the process container 210, and the internal surface of the exhaust pipe 224 (Step S56).

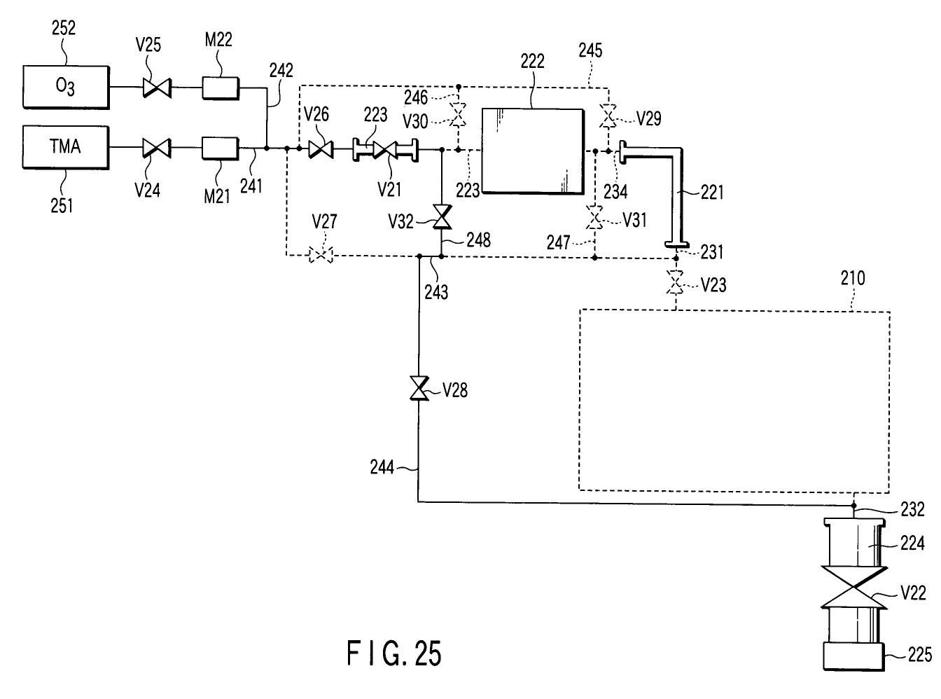

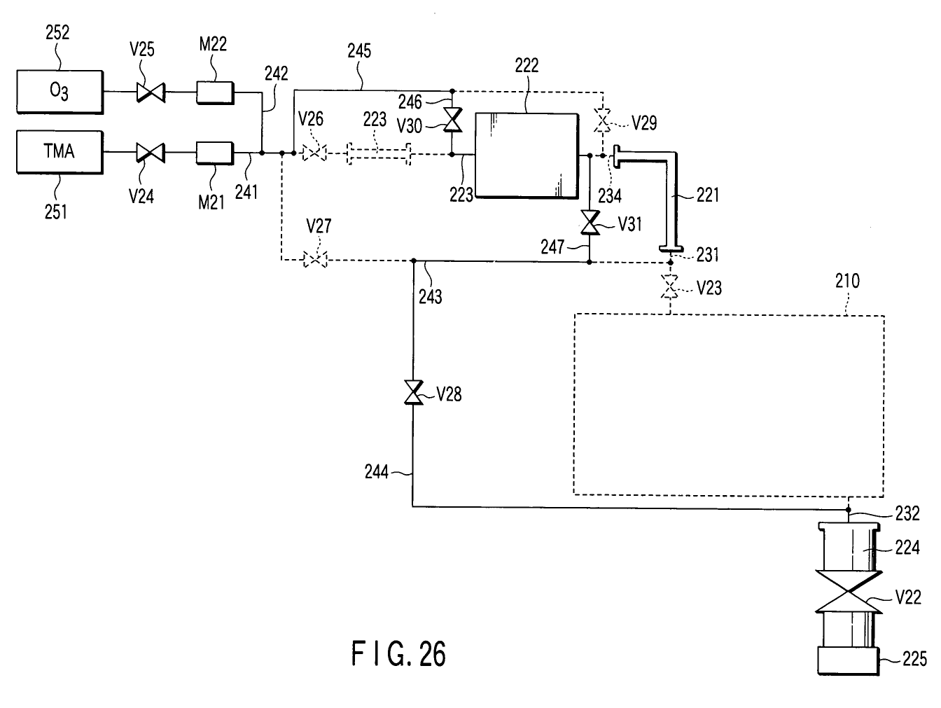

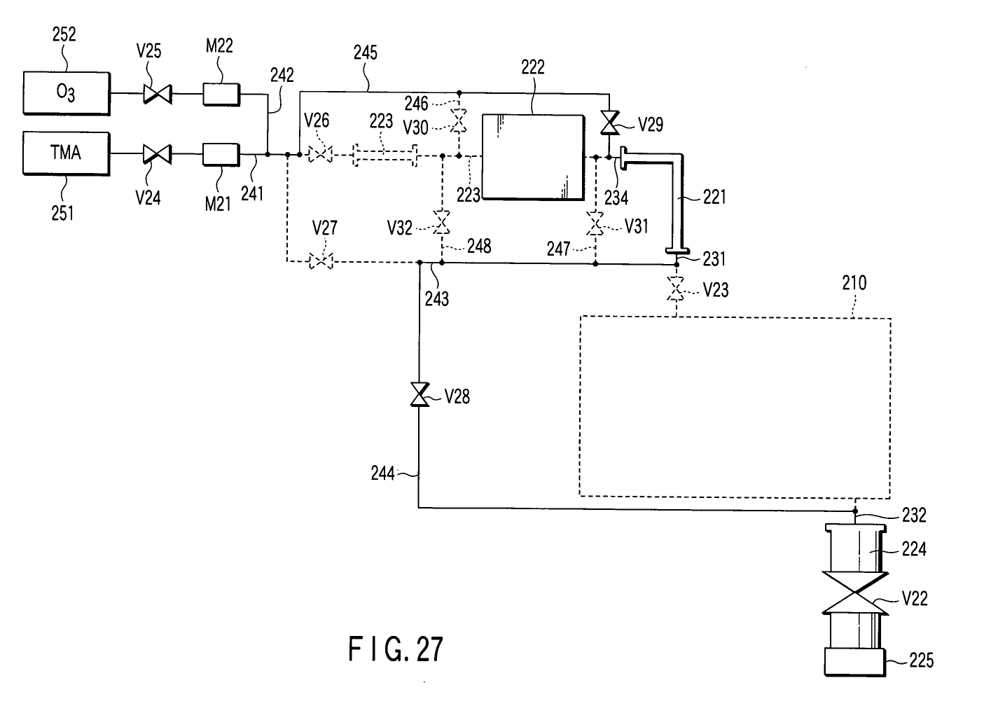

FIG. 25 is a structural view showing an arrangement for performing a surface preparation only of a gas pipe for supplying a process gas into a process container, by the surface preparation apparatus shown in FIG. 19. FIG. 26 is a structural view showing an arrangement for performing a surface preparation only of a gas supply unit disposed on a process gas supply line, by the surface preparation apparatus shown in FIG. 19. FIG. 27 is a structural view showing an arrangement for performing a surface preparation only of a process gas supply line for supplying a process gas into a process container, by the surface preparation apparatus shown in FIG. 19.

For example, where a surface preparation is performed only for the gas pipe 223, process gas supply pipe 221, or gas supply unit 222, as shown in FIGS. 25 to 27, the corresponding one of the gas pipe 223, gas supply unit 222, process gas supply pipe 221 is connected by use of a pipe 233 and/or a pipe 234 for connecting a by-pass passage. Further, third to sixth by-pass passages 245 to 248 are selectively disposed, as follows. Specifically, the third by-pass passage 245 provided with a switching valve V29 is branched from the first source material flow passage 241 upstream from the switching valve V26, and is connected to the pipe 234 at the other end. The fourth by-pass passage 246 provided with a valve V30 is branched from this third by-pass passage 245, and is connected to the pipe 223 at the other end. The fifth by-pass passage 247 provided with a valve V31 connects the pipe 234 to the first by-pass passage 243. The sixth by-pass passage 248 provided with a valve V32 connects the pipe 233 to the first by-pass passage 243. Consequently, a process is performed by supplying the first and second source gases only to a component selected for a surface preparation while vacuum exhausting the selected component.

Where a surface preparation is performed only for the gas pipe 223, as shown in FIG. 25 for example, the first and second source gases are supplied into the gas pipe 223 by use of the first and second source material flow passages 241 and 242, sixth by-pass passage 248, first by-pass passage 243, second by-pass passage 244, and exhaust pipe 224. Further, the gas pipe 223 is vacuum-exhausted through the sixth by-pass passage 248, first and second by-pass passages 243 and 244, and exhaust pipe 224.

Where a surface preparation is performed only for the gas supply unit 222, as shown in FIG. 26 for example, the first and second source gases are supplied into the gas supply unit 222 by use of the first and second source material flow passages 241 and 242, third by-pass passage 245, fourth by-pass passage 246, the fifth by-pass passage 247, first and second by-pass passages 243 and 244, and exhaust pipe 224. Further, the gas supply unit 222 is vacuum-exhausted through the fifth by-pass passage 247, first and second by-pass passages 243 and 244, and exhaust pipe 224.

Where a surface preparation is performed only for the process gas supply pipe 221, as shown in FIG. 27 for example, the first and second source gases are supplied into the process gas supply pipe 221 by use of the first and second source material flow passages 241 and 242, third by-pass passage 245, first and second by-pass passages 243 and 244, and exhaust pipe 224. Further, the process gas supply pipe 221 is vacuum-exhausted through the first and second by-pass passages 243 and 244 and exhaust pipe 224.

Where a surface preparation is performed only for the exhaust pipe 224, for example, the first and second source gases are supplied into the exhaust pipe 224 by use of the first and second source material flow passages 241 and 242, third by-pass passage 245, and first and second by-pass passages 243 and 244. Further, the exhaust pipe 224 is vacuum-exhausted through the exhaust pipe 224.

In the examples described above, the second by-pass passage 244 is connected on the upstream side of the exhaust pipe 224, but the by-pass passage 244 may be connected to a middle of the exhaust pipe 224. The by-pass passage 244 or another new by-pass passage (not shown) may be connected to the downstream side of the exhaust pipe 224, so that the pipe 223, gas supply unit 222, process gas supply pipe 221, and/or process container 210 can be vacuum-exhausted directly by the vacuum pump 225 without using a route through the exhaust pipe 224. Since the ALD film can be formed even at a low temperature, such as room temperature, heating by the heating means 253 to 257, such as a tape heater and/or resistive heating body, is not necessarily required.

Further, for example, by use of the connection arrangement shown in FIG. 18, a surface preparation may be performed together for a corrosive gas flow passage extending from the gas pipe 223 through the gas supply unit 222, process gas supply pipe 221, and process container 210 to the exhaust pipe 224. Specifically, in this case, the process gas supply pipe 221 and exhaust pipe 224 are directly attached to the process container 210. Further, in place of the gas supply source 202, the supply sources 251 and 252 of the first and second source gases are connected to the upstream side of the gas pipe 223.

In this embodiment, the process gas supply pipe 221 is combined with the gas pipe 223 to form a line for supplying a process gas into the process container 210. However, the gas pipe 223 on the user side is not necessary required. Further, the gas supply unit 222 may be omitted.

In this embodiment, the apparatus is assembled on the user side, but the apparatus may be assembled on the maker side such that the process gas supply pipe 221 and the exhaust pipe 224 connected to the vacuum pump 225 are attached to the process container 210. In this case, the first and second source gas supply sources 251 and 252 are connected to the upstream side of the process gas supply pipe 221, and then a surface preparation is performed for the corrosive gas flow passage of the apparatus thus assembled.

As the ALD film described above, an organo-metallic compound containing aluminum (Al), hafnium (Hf), zirconium (Zr), or yttrium (Y) may be used in place of an Al₂O₃ film formed by the method described above. Alternatively, the ALD film may be made of a compound, such as a chloride containing aluminum (Al), hafnium (Hf), zirconium (Zr), or yttrium (Y).

In this respect, specific examples are as follows. A first source gas comprising AlCl₃ gas and a second source gas comprising O₃ gas or H₂O gas are used to form Al₂O₃. A first source gas comprising HfCl₄ gas and a second source gas comprising O₃ gas are used to form HfO₂. A first source gas comprising Hf(N(CH₃)(C₂H₅))₄ gas and a second source gas comprising O₃ gas or H₂O gas are used to form HfO₂. A first source gas comprising Hf(N(C₂H₅)₂)₄ gas and a second source gas comprising O₃ gas or H₂O gas are used to form HfO₂. A first source gas comprising ZrCl₄ gas and a second source gas comprising O₃ gas or H₂O gas are used to form ZrO₂. A first source gas comprising Zr(T-OC₄H₉)₄ gas and a second source gas comprising O₃ gas or H₂O gas are used to form ZrO₂. A first source gas comprising YCl₃ gas and a second source gas comprising O₃ gas or H₂O gas are used to form Y₂O₃. A first source gas comprising Y(C₅H₅)₃ gas and a second source gas comprising O₃ gas or H₂O gas are used to form Y₂O₃.

According to this embodiment, at first, the semiconductor processing apparatus is assembled such that the process container 210 is connected to the process gas supply pipe 221 and the vacuum pump 225 through the exhaust pipe 224. Then, the first and second source gases are alternately supplied, by switching a number of times, into the corrosive gas flow passage of the semiconductor processing apparatus. Further, the interior of the flow passage is vacuum-exhausted between the supply periods of the first and second source gases. Where a deposition film is formed inside the flow passage by this ALD method, an ALD film can be formed all over the area of the semiconductor processing apparatus that comes in contact with a corrosive gas. Consequently, the corrosion resistance of this area relative to the corrosive gas is improved.

Specifically, according to this ALD film, very thin deposition films are laminated, or atomic layers are stacked one by one, to form an ALD film. Consequently, the film is formed as a dense film having high durability and corrosion resistance against a corrosive process gas. Further, the film thus formed by laminating atomic layers has a high surface flatness, which can prevent film peeling or the like from occurring due to surface roughness.

According to this embodiment, after the semiconductor processing apparatus is assembled, the source gases are supplied into the corrosive gas flow passage of this apparatus, so as to perform a surface preparation of components located within an area where a corrosive gas flows through. Consequently, the source gases are supplied onto the portions of the components that come in contact with the corrosive gas, so that an ALD film is formed thereon.

Further, as described above, a surface preparation is performed after the semiconductor processing apparatus is assembled. In this case, even where the gas pipe 223 on the user side is connected to the upstream side of the process gas supply pipe 221 attached to the process container 210, the source gases can be supplied from the upstream side of the gas pipe 223, so that a surface preparation is performed also for the gas pipe 223 on the user side. Consequently, even where the apparatus needs to use a pipe on the user side, which has not be sufficiently subjected to a maintenance operation, it is possible to suppress particle generation due to corrosion of this pipe, and thus to prevent metal contamination.

When the apparatus is assembled, a surface preparation film may be broken by external factors, such as a pipe bending process. However, where a surface preparation is performed after a pipe bending process, a dense ALD film is formed on the surface of the broken film. Consequently, the broken film is prevented from developing film peeling or particle generation.

Where the process container 210 and a component attached thereto are separately processed, it is necessary to perform operations such that the component is detached from the process container 210 and is processed, and then the component is attached to the process container 210. In this respect, where a surface preparation is performed after the component is attached inside the process container 210, the surface preparation can be performed together for the process container 210 and the component inside the process container 210. Consequently, some of the operations described above are unnecessary, which allows the entire process to be performed more easily in a shorter time.

Since a vacuum process is used to form an ALD film, the source gases are delivered to narrow places in complex shapes, such as the gas supply unit 222, to form the ALD film on such places. At this time, the ALD film is formed by laminating very thin layers one by one, as described above. Accordingly, the thickness of the ALD film can be set at a desired value by controlling the number of repetitions of Steps S32 to S35 described above. For example, depending on the surface preparation target object, the thickness of the ALD film can be easily adjusted.

Where a gas flow passage has a complex shape, such as the gas supply unit 222, the first and second source gases are selectively supplied into the gas supply unit 222 while the gas supply unit 222 is vacuum-exhausted. By doing so, a surface preparation is performed for the gas supply unit 222 to form an ALD film having a small film thickness. In this case, it is possible to improve the corrosion resistance of the gas supply unit 222 relative to a corrosive gas without impeding the gas flow conductance.

Vacuum exhaust is performed between the supply periods of the first and second source gases, so that the second source gas is supplied in a state where no first source gas remains. In this case, the first and second source gases are prevented from reacting with each other inside a component set as a surface preparation target object, and thus particle generation due to reaction products is suppressed.

As described above, a dense film can be formed all over the surface that comes in contact with a corrosive gas within an area where the corrosive gas flows through in a semiconductor processing apparatus. Consequently, the corrosion resistance of the area relative to a corrosive process gas is improved. Further, particle generation due to corrosion of the area is suppressed.

The ALD film is formed by a process at a temperature of, e.g., from about room temperature to 200° C., which is lower than that used in thermal CVD methods in general. Accordingly, even for a process container made of, e.g., aluminum or aluminum with a thermal spray film formed thereon, a surface preparation can be performed without melting aluminum. Where the ALD film is formed on a thermal spray film, which is porous, the ALD film is formed from compound layers that intrude a number of holes of the thermal spray film, and thus the ALD film becomes stronger. In this case, the corrosion resistance of the thermal spray film, which is originally high, is enhanced by the dense ALD film formed on the thermal spray film. Further, a weak point of the thermal spray film, i.e., the porous structure or surface roughness thereof, can be compensated for by the ALD film. Consequently, even where a corrosive process gas is used, it is possible to prevent film peeling from occurring during the process.

Also in a case where a surface preparation is performed for a metal pipe, the ALD film is formed by a low temperature process, as described above. At this time, the reaction between the first and second source gases can sufficiently proceed even by heating of the tape heater. Accordingly, the process can be performed by use of a simple heating method.

As described above, according to this embodiment, a surface preparation is performed to form a deposition film on a component made of aluminum or stainless steel, such as a process container, pipe, or bottom member, in a state where it has not undergone a surface preparation, and thus is inexpensive. Consequently, the durability of the component and the corrosion resistance thereof relative to a corrosive gas are improved. In this case, a semiconductor manufacturing apparatus can be assembled from inexpensive components, without purchasing expensive components processed by a surface preparation in advance, so the manufacturing cost of the apparatus can be decreased.

The arrangement shown in FIG. 19 can be used as an apparatus for performing a surface preparation of a component. In this case, a surface preparation can be performed while the switching valves on the source material supply passages are switched to selectively supply the first and second source gases to a surface preparation target object, which is being vacuum-exhausted. Accordingly, a single apparatus can be used to selectively perform a surface preparation for any one or all of the process gas supply pipe 221, process container 210, gas pipe 223, and gas supply unit 222, so the apparatus has high versatility.

Since a surface preparation can be selectively performed for one of the components, a surface preparation need only be performed for the member that requires it when a start-up operation or a maintenance operation is performed. Further, as described above, the ALD film can be formed to have a suitable film thickness on each component. Incidentally, this embodiment may be modified such that an alumite process is first performed on the metal of a pipe and/or a process container, and the ALD film is formed thereon.

### Matters Common to First to Third Embodiments

Components provided by the first to third embodiments for semiconductor processing apparatuses include the following arrangement in common. Specifically, each component comprises a matrix defining the shape of the component, and a protection film (which is referred to as a deposition film, ALD film, or intermediate layer in the embodiments) covering a predetermined surface of the matrix. The protection film is made of an amorphous oxide of a first element selected from the group consisting of aluminum, silicon, hafnium, zirconium, and yttrium.

The protection film has a porosity of less than 1%, and preferably of less than 0.1%. In other words, the protection film is so compact that it has essentially no pores. If the protection film has a porosity of 1% or more, the protection for the matrix surface may be insufficient. Further, the protection film has a thickness of 1 nm to 10 μm, and preferably of 1 nm to 1 μm. If the protection film has a thickness of 1 nm or less, the protection for the matrix surface may be insufficient. In this respect, along with an increase in the thickness of the protection film, the ALD process requires more time, but its protection effect is essentially maximized. Accordingly, the protection film is set to have a thickness within the range described above.

Such a protection film, which is made of an amorphous oxide of the first element and compact and very thin, may be formed by an ALD method to perform a film formation process on a matrix defining the shape of a component. In this case, a method for manufacturing a component comprises: preparing a matrix defining the shape of the component; and forming a protection film covering a predetermined surface of the matrix. The protection film may be formed by alternately supplying a first source gas containing the first element and a second source gas containing an oxidation gas, thereby laminating layers formed by CVD and having a thickness of an atomic or molecular level.

In this respect, a thermal spray film conventionally used as a protection film is formed of a poly-crystalline film having a porosity of about 8%, in general. Further, with a thermal spray film, it is difficult to form a thin film of 10 μm or less. In another case, a film formed by coating and baking is used as a protection film. The film of this type is formed of a poly-crystal and has a relatively large film thickness.

Typical components used for semiconductor processing apparatuses and provided with a protection film formed thereon as described above are members used for forming a part of any one of the process field, exhaust system, and gas supply system, and thus are exposed to a corrosive atmosphere. Components of this kind are exemplified by a sidewall of a process chamber, a manifold that forms a bottom of a process chamber, a deposition shield that covers an internal surface of a process chamber, a focus ring, a gas supply line, and an exhaust line. In other words, the matrix of a component preferably defines the shape of any one of these members. Further, the matrix to be protected by the protection film typically comprises a material selected from the group consisting of aluminum and stainless steel.

The surface of the matrix of a component of this kind may be covered with a thermal spray film. In this case, a protection film is formed on this thermal spray film serving as an underlying film, i.e., the component thereby prepared further includes the underlying film interposed between the matrix surface and protection film. This underlying film is made of an oxide of a second element preferably selected from the group consisting of boron, magnesium, aluminum, silicon, gallium, chromium, yttrium, zirconium, germanium, tantalum, and neodymium.

As described with reference to the second embodiment, a thermal spray film may be further formed on a protection film, as a covering film. In this case, the component thereby prepared further includes the covering film that covers the protection film. The covering film is made of an oxide of a third element preferably selected from the group consisting of aluminum, silicon, hafnium, zirconium, and yttrium. Further, in this case, before the protection film is formed, a surface roughening process, such as a sand abrasive blasting process, is preferably performed on the matrix surface.

### INDUSTRIAL APPLICABILITY

The present invention is applied to a component with high durability for a semiconductor processing apparatus, a manufacturing method thereof, and a semiconductor processing apparatus using the component.

1. A component for a semiconductor processing apparatus, the component comprising:
a matrix defining a shape of the component; and
a protection film covering a predetermined surface of the matrix,
wherein the protection film consists essentially of an amorphous oxide of a first element selected from the group consisting of aluminum, silicon, hafnium, zirconium, and yttrium, and has a porosity of less than 1% and a thickness of 1 nm to 10 μm.

2. The component according to claim 1, wherein the protection film is a film formed by alternately supplying a first source gas containing the first element and a second source gas containing an oxidation gas, thereby laminating layers formed by CVD (Chemical Vapor Deposition) and having a thickness of an atomic or molecular level.

3. The component according to claim 1, further comprising an underlying film interposed between the predetermined surface and the protection film, and consisting essentially of an oxide of a second element.

4. The component according to claim 3, wherein the underlying film is a film formed by thermal spray.

5. The component according to claim 3, wherein the second element is selected from the group consisting of boron, magnesium, aluminum, silicon, gallium, chromium, yttrium, zirconium, germanium, tantalum, and neodymium.

6. The component according to claim 1, further comprising a covering film covering the protection film, and consisting essentially of an oxide of a third element.

7. The component according to claim 6, wherein the covering film is a film formed by thermal spray.

8. The component according to claim 6, wherein the third element is selected from the group consisting of aluminum, silicon, hafnium, zirconium, and yttrium.

9. The component according to claim 6, wherein the predetermined surface is a surface treated by a surface roughening process.

10. The component according to claim 1, wherein the matrix comprises a material selected from the group consisting of aluminum and stainless steel.

11. The component according to claim 1, wherein the matrix defines a shape of a member selected from the group consisting of a sidewall of a process chamber, a manifold that forms a bottom of a process chamber, a deposition shield that covers an internal surface of a process chamber, a focus ring, a gas supply line, and an exhaust line.

12. A method for manufacturing a component used for a semiconductor processing apparatus, the method comprising:
preparing a matrix defining a shape of the component; and
forming a protection film covering a predetermined surface of the matrix,
wherein said forming a protection film comprises alternately supplying a first source gas containing a first element and a second source gas containing an oxidation gas, thereby laminating layers formed by CVD (Chemical Vapor Deposition) and having a thickness of an atomic or molecular level, and wherein the first element is selected from the group consisting of aluminum, silicon, hafnium, zirconium, and yttrium.

13. The manufacturing method according to claim 12, wherein the protection film consists essentially of an amorphous oxide of the first element, and has a porosity of less than 1% and a thickness of 1 nm to 10 μm.

14. The manufacturing method according to claim 12, wherein the matrix comprises a material selected from the group consisting of aluminum and stainless steel.

15. The manufacturing method according to claim 12, wherein an underlying film is interposed between the predetermined surface and the protection film, and consists essentially of an oxide of a second element selected from the group consisting of boron, magnesium, aluminum, silicon, gallium, chromium, yttrium, zirconium, germanium, tantalum, and neodymium.

16. The manufacturing method according to claim 12, wherein the method further comprises forming a covering film by thermal spray to cover the protection film, the covering film consisting essentially of an oxide of a third element.

17. The manufacturing method according to claim 16, wherein the third element is selected from the group consisting of aluminum, silicon, hafnium, zirconium, and yttrium.

18. The manufacturing method according to claim 16, wherein the method further comprises performing a surface roughening process on the predetermined surface.

19. A semiconductor processing apparatus comprising:
a process container having a process field configured to accommodate a target substrate;
a support member configured to support the target substrate within the process field;
an exhaust system configured to exhaust the process field; and
a gas supply system configured to supply a process gas into the process field,
wherein a component forming a part of one of the process field, the exhaust system, and the gas supply system comprises
a matrix defining a shape of the component, and
a protection film covering a predetermined surface of the matrix, and
wherein the protection film consists essentially of an amorphous oxide of an element selected from the group consisting of aluminum, silicon, hafnium, zirconium, and yttrium, and has a porosity of less than 1% and a thickness of 1 nm to 10 μm.

20. The semiconductor processing apparatus according to claim 19, further comprising a covering film covering the protection film, and consisting essentially of an oxide of an element selected from the group consisting of aluminum, silicon, hafnium, zirconium, and yttrium.
